(19) United States
(12) Patent Application Publication
(10) Pub. No.: US 2024/0044828 A1
(43) Pub. Date: Feb. 8, 2024

(54) SUBSTRATE, PACKAGE, SENSOR DEVICE, AND ELECTRONIC APPARATUS

(71) Applicant: KYOCERA Corporation, Kyoto-shi, Kyoto (JP)

(72) Inventor: Koutarou NAKAMOTO, Kyoto-shi (JP)

(73) Assignee: KYOCERA Corporation, Kyoto-shi, Kyoto (JP)

(21) Appl. No.: 18/266,650

(22) PCT Filed: Dec. 13, 2021
(86) PCT No.: PCT/JP2021/045724

§ 371 Date: Jun. 12, 2023

(30) Foreign Application Priority Data
Dec. 18, 2020 (JP) 2020-210677

(51) Int. Cl. G01N 27/12; H04R 1/44; H04R 1/10

(52) U.S. Cl. CPC G01N 27/121; G01N 27/125; H04R 1/44; H04R 1/1066

(57) ABSTRACT

A substrate includes: a first layer that is a ceramic insulation layer including a plurality of first through holes; and a second layer layered on the first layer, the second layer being a ceramic insulation layer including at least one second through hole. The plurality of first through holes each have a diameter of from 10 μm to 50 μm, and the diameter of the at least one second through hole is larger than the diameter of each of the plurality of first through holes. At least some of the plurality of first through holes overlap the at least one second through hole.

### TECHNICAL FIELD

The present disclosure relates to a substrate and a package mounted with an element, a sensor device mounted with the element, and an electronic apparatus including the sensor device.

### BACKGROUND OF INVENTION

Mobile devices such as smartphones are mounted with various sensors. In particular, sensors for detecting a property of gas include a through hole for ventilation, and thus a waterproof sheet is attached to a housing of the device to improve waterproof property. Unfortunately, sheets normally used as the waterproof sheet are expensive. A step of attaching the waterproof sheet to the inside of the housing is also required. In small devices, attaching the waterproof sheet may be structurally difficult. Therefore, there has been a demand for a substrate and a sensor device having a waterproof structure and excellent breathability.

Patent Document 1 discloses a waterproof cover body structure including microchannels with a diameter of from 0.1 mm to 0.6 mm and a length of from 1 mm to 5 mm.

Patent Document 2 discloses a plate-shaped waterproof member made of silicon (Si) or the like. The waterproof member includes a plurality of through holes extending through the upper and lower surfaces thereof.

### CITATION LIST

### Patent Literature

Patent Document 1: JP 3201758 UM-B

Patent Document 2: JP 2019-124499 A

### SUMMARY

In an embodiment of the present disclosure, a substrate includes: a first layer that is a ceramic insulation layer including a plurality of first through holes; and a second layer layered on the first layer, the second layer being a ceramic insulation layer including at least one second through hole. The plurality of first through holes each have a diameter of from 10 μm to 50 μm. The at least one second through hole has a diameter larger than the diameter of each of the plurality of first through holes. At least some of the plurality of first through holes overlap the at least one second through hole in plan view of the first layer.

In an aspect of the present disclosure, a package includes: the substrate that is a lid body; and a wiring board including an accommodation recess and wiring, the accommodation recess being configured to accommodate a sensor element. The first layer is located on the accommodation recess side. The diameter of the at least one second through hole is 100 μm or more and 200 μm or less, and V′/V≥0.05%, where V is a volume defined by a surface of the first layer on the side of the accommodation recess and the accommodation recess, and V′ is the sum of the volumes of the plurality of first through holes and the at least one second through hole.

In an aspect of the present disclosure, a sensor device includes the substrate and a sensor element.

In an aspect of the present disclosure, a sensor device includes the package and a sensor element.

In an aspect of the present disclosure, an electronic apparatus includes the sensor device.

In an aspect of the present disclosure, a package includes: a first substrate including an accommodation recess configured to accommodate a sensor element; and a second substrate configured to close the accommodation recess. The second substrate includes: a first layer that is a ceramic insulation layer including a plurality of first through holes; and a second layer layered on the first layer. the second layer being a ceramic insulation layer including at least one second through hole. The plurality of first through holes each have a diameter of from 10 μm to 50 μm. The at least one second through hole has a diameter larger than the diameter of each of the plurality of first through holes. At least some of the plurality of first through holes overlap the at least one second through hole in plan view of the first layer. The second layer is located on the accommodation recess side.

In an aspect of the present disclosure, a substrate is to be mounted with a sensor element. The substrate includes: a first layer that is a ceramic insulation layer including a plurality of first through holes; a second layer layered on the first layer, the second layer being a ceramic insulation layer including at least one second through hole; a frame portion positioned on a surface of the second layer and surrounding the plurality of first through holes and the at least one second through hole; and a wiring conductor. The plurality of first through holes each have a diameter of from 10 μm to 50 μm. The at least one second through hole has a diameter larger than the diameter of each of the plurality of first through holes. At least some of the plurality of first through holes overlap the at least one second through hole in plan view of the first layer.

In an aspect of the present disclosure, a sensor device includes the substrate and a sensor element.

In an aspect of the present disclosure, a sensor device includes the package and a sensor element.

In an aspect of the present disclosure, an electronic apparatus includes the sensor device.

### BRIEF DESCRIPTION OF THE DRAWINGS

FIG. 1 is a cross-sectional view of an exemplary substrate according to a first embodiment of the present disclosure.

FIG. 2 is a cross-sectional view of another exemplary substrate according to the first embodiment of the present disclosure.

FIG. 3 is an exemplary SEM photograph illustrating a cross-section of a first through hole formed in a first layer according to the first embodiment of the present disclosure.

FIG. 4 is a schematic cross-sectional view of the first layer according to the first embodiment of the present disclosure.

FIG. 5 illustrates a plan view of a main part of the substrate according to the first embodiment of the present disclosure, and an enlarged cross-sectional view of the substrate.

FIG. 6 illustrates a comparative example with respect to FIG. 5.

FIG. 7 is a schematic cross-sectional view of the first layer and a plan view of the first through hole.

FIG. 8 is a schematic cross-sectional view of the first layer.

FIG. 9 is a schematic plan view illustrating an example of an arrangement of the first through holes in plan view of the substrate 1.

FIG. 10 is a schematic plan view illustrating an example of an arrangement of the first through holes in plan view of the substrate 1.

FIG. 11 is a view illustrating an outline of a device used in a waterproof test.

FIG. 12 is a cross-sectional view of an evaluation sample used in the waterproof test.

FIG. 13 is a cross-sectional view of a gas sensor device according to a second embodiment of the present disclosure.

FIG. 14 is a cross-sectional view of another exemplary gas sensor device according to the second embodiment of the present disclosure.

FIG. 15 is a cross-sectional view of another exemplary gas sensor device according to the second embodiment of the present disclosure.

FIG. 16 is a cross-sectional view of another exemplary gas sensor device according to the second embodiment of the present disclosure.

FIG. 17 is a cross-sectional view of a package according to the second embodiment of the present disclosure.

FIG. 18 is a cross-sectional view of another exemplary gas sensor device according to the second embodiment of the present disclosure.

FIG. 19 is a cross-sectional view of another exemplary gas sensor device according to the second embodiment of the present disclosure.

FIG. 20 is a cross-sectional view of a sensor device according to the second embodiment of the present disclosure.

FIG. 21 is a cross-sectional view of the sensor device according to the second embodiment of the present disclosure.

FIG. 22 is a cross-sectional view of an exemplary substrate according to a third embodiment of the present disclosure.

FIG. 23 is a perspective view of the substrate according to the third embodiment of the present disclosure.

FIG. 24 is a cross-sectional view of a gas sensor device according to a fourth embodiment of the present disclosure.

FIG. 25 is a cross-sectional view of an atmospheric pressure sensor device according to the fourth embodiment of the present disclosure.

FIG. 26 is a cross-sectional view of the gas sensor device according to the fourth embodiment of the present disclosure.

FIG. 27 is a cross-sectional view of the atmospheric pressure sensor device according to the fourth embodiment of the present disclosure.

FIG. 28 is a cross-sectional view of an electronic apparatus including the gas sensor device according to the second embodiment.

FIG. 29 is a cross-sectional view of an electronic apparatus including the gas sensor device according to the fourth embodiment.

FIG. 30 is a cross-sectional view of an electronic apparatus including the gas sensor device according to the second embodiment.

FIG. 31 is a cross-sectional view of an electronic apparatus including the atmospheric pressure sensor device according to the fourth embodiment.

FIG. 32 is a cross-sectional view of an electronic apparatus including the gas sensor device according to the fourth embodiment.

FIG. 33 is a cross-sectional view of an electronic apparatus including the gas sensor device according to the fourth embodiment.

### DESCRIPTION OF EMBODIMENTS

### First Embodiment

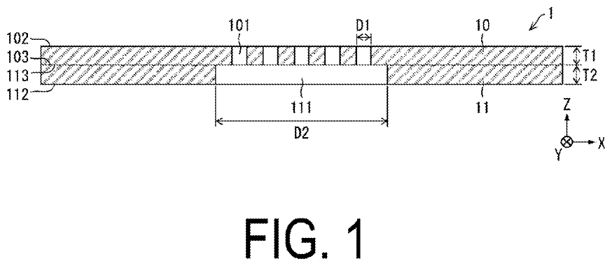

An embodiment of the present disclosure will be described in detail below with reference to accompanying drawings. FIG. 1 is a cross-sectional view of an exemplary substrate 1 according to a first embodiment of the present disclosure taken along a plane perpendicular to the substrate 1 and parallel to an X axis direction. In the drawings, an X-Y plane is a plane parallel to an upper surface or a bottom surface of the substrate 1, and a Z axis is an axis orthogonally intersecting the X-Y plane. Cross-sectional views of the substrate in the present specification are taken along a plane that is the same as and/or similar to that in FIG. 1 unless otherwise specified. Cross-sectional views of a package and a sensor device described below that include the substrate is also taken along a plane that is the same as and/or similar to that in FIG. 1 unless otherwise specified.

As illustrated in FIG. 1, in the substrate 1, a first layer 10 including a plurality of first through holes 101 and a second layer 11 including at least one second through hole 111 are layered on each other. The first layer 10 includes a 1-1 surface 102 forming one outer surface of the substrate 1 and a 1-2 surface 103 on the side facing the second layer 11. The second layer 11 includes a 2-1 surface 112 forming the other outer surface of the substrate 1 and a 2-2 surface 113 on the side facing the first layer 10. Each of the first layer 10 and the second layer 11 is an insulation layer made of an insulation material containing a ceramic material such as an aluminum oxide-based sintered body, a glass ceramic sintered body, a mullite-based sintered body, or an aluminum nitride-based sintered body, for example. In the substrate 1, a plurality of the first through holes 101 overlap one of the second through hole 111 in plan view of the substrate 1 as viewed from the 2-1 surface 112 side. The substrate 1 has, for example, a quadrangular shape such as a rectangular shape or a square shape in plan view.

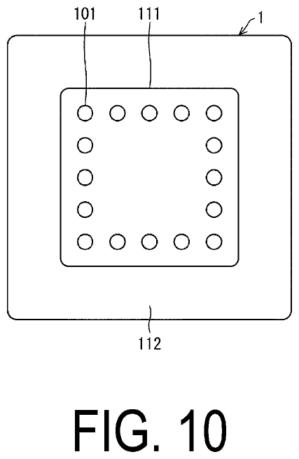

With the Z axis direction defined as the thickness direction, in the substrate 1, the first layer 10 has a thickness T1 of, for example, 50 μm or more and 150 μm or less. In the 1-1 surface 102, the first through hole 101 has, for example, a circular shape, and has a diameter D1 of 10 μm or more and 50 μm or less. When the diameter of the first through hole is not uniform in a depth direction, the smallest diameter is 10 μm or more and 50 μm or less. For example, when the diameters D1 of the first through hole 101 differ between the 1-1 surface 102 and the 1-2 surface 103, the smaller diameter is 10 μm or more and 50 μm or less. The second layer 11 has a thickness T2 of, for example, 50 μm or more and 200 μm or less. In the 2-1 surface 112, the second through hole 111 has, for example, a circular shape, and has a diameter D2 larger than the diameter D1 of the first through hole 101. The diameter D2 of the second through hole 111 is, for example, 0.5 mm or more and 2 mm or less. The cross-sectional shape of the first through hole 101 and the second through hole 111 in a plane (X-Y plane) parallel to the substrate 1 is not limited to circular shapes, and may have a polygonal shape such as a quadrangular shape as in an example illustrated in FIG. 10 described below. In this case, for the dimensions of the first through hole 101 and the second through hole 111, the length of a side of the quadrangle corresponds to the diameter D1 and the diameter D2 described above, for example.

FIG. 1 illustrates an example in which the substrate 1 is constituted by two layers, the first layer 10 and the second layer 11. However, the substrate 1 is not limited to being two-layered. In the substrate 1, the first layer 10 and the second layer 11 may be directly layered on each other, or may be layered with another layer interposed therebetween.

The substrate 1 is a laminate body (ceramic body) containing, for example, an aluminum oxide-based sintered body, and can be fabricated in the following manner. First, ceramic green sheets (green sheets) to be the first layer 10 and the second layer 11 are produced. Raw material powder of aluminum oxide, silicon oxide, or the like is formed into a sheet shape together with an appropriate organic binder and an organic solvent to produce a plurality of ceramic green sheets having a quadrangular sheet shape. The first through hole 101 is formed, for example, in the ceramic green sheet corresponding to the first layer 10 by punching using a die or the like. The hole diameter at the time of punching is such that the hole diameter after firing is 10 μm or more and 50 μm or less. The second through hole 111 is formed, for example, in the ceramic green sheet corresponding to the second layer 11 using a die or the like. The first through hole 101 and the second through hole 111 may be formed using a laser. These ceramic green sheets are layered on each other to produce a laminate body. Then, this laminate body can be fired at a temperature of from 1300° C. to 1600° C. to fabricate the substrate 1.

Since the ceramic green sheet shrinks upon firing by approximately 10% to 20%, the hole formed in the green sheet can have a hole diameter larger than the diameter of the first through hole 101 and the second through hole 111 after firing by approximately 10% to 20%. Since the ceramic green sheet before firing is a soft material, fine hole processing as described above is easy. Thus, when the substrate 1 is formed of a ceramic laminate body, fine through holes having, for example, a diameter of 100 μm or less can be easily formed, which is generally considered to be difficult with metal substrates or organic substrates. The method of forming fine through holes in the ceramic green sheet using a die or the like has higher productivity than a method of forming through holes in a substrate made of silicon or the like by etching. That is, using ceramic can improve productivity.

The thinner the ceramic green sheet is, the easier it is to form fine through holes. By using a thin green sheet as the ceramic green sheet forming the first layer 10, a fine first through hole 101 can be easily formed. The ceramic green sheet forming the second layer 11 can have a thickness and the number of layers corresponding to the strength required for the substrate 1. In other words, one or more insulation layers having the same configuration as that of the second layer 11 may be layered on the second layer 11. As the substrate 1 is a laminate body in which the first layer 10 including the fine first through hole 101 and another layer, that is, the second layer 11 are layered on each other, the substrate 1 can easily secure the required substrate thickness while including fine through holes.

With the substrate 1 having the fine first through holes 101, a substrate through which gas passes but water does not easily pass can be obtained. With the diameter D1 of the first through hole 101 being 10 μm or more and 50 μm or less, a structure through which water does not easily pass can be obtained. With the diameter D1 of the first through hole 101 being 10 μm or more, good breathability can be achieved. With ceramic used as the material of the substrate 1, the first through hole 101 having the diameter D1 of 10 μm or more can be easily formed. With the diameter D1 of the first through hole 101 being 10 μm or more and 50 μm or less and with the thickness T1 of the first layer 10 being 50 μm or more and 150 μm or less, a substrate can be obtained that has the waterproof property of the IPX7 level or higher and excellent breathability. Since the depth of the first through hole 101 (which is equal to the thickness T1 of the first layer) is smaller than the thickness (T1+T2) of the substrate 1, breathability can be improved. On the other hand, the strength can be secured with the second layer 11 layered on the first layer 10.

Since the substrate 1 has a layered structure of ceramic insulation layers, strength high enough for protecting an element and the like accommodated inside can be secured. With ceramic used as the material of the substrate 1, corrosion and deterioration due to water or gas can be reduced as compared with cases where a metal or organic material is used. With ceramic used as the material of the substrate 1, the substrate 1 can have high strength as compared with cases where silicon is used. Thus, the substrate 1 can be reduced in thickness. Since the substrate 1 has high strength, the number of through holes can be increased, whereby breathability can be improved.

### Variation 1-1

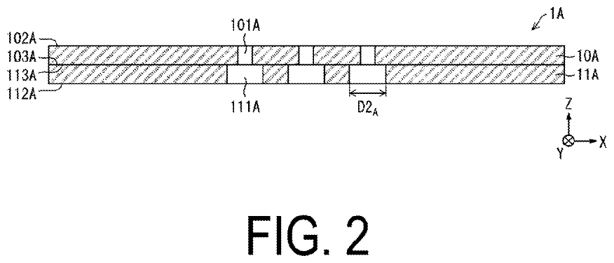

FIG. 2 is a cross-sectional view of another exemplary substrate 1A according to the first embodiment. As illustrated in FIG. 2, the substrate 1A is different from the above-described substrate 1 in that one first through hole 101 overlaps one second through hole 111A in plan view of the substrate 1A as viewed from the side of a 2-1 surface 112A. Members having the same functions as the members described in the embodiment described above are denoted by the same reference signs, and descriptions thereof will not be repeated. The same applies to other variations and embodiments.

Specifically, as illustrated in FIG. 2, in the substrate 1A, a first layer 10A including a plurality of the first through holes 101A and a second layer 11A including a plurality of second through holes 111A are layered on each other. The first layer 10A includes a 1-1 surface 102A forming one outer surface of the substrate 1A and a 1-2 surface 103A on the side facing the second layer 11A. The second layer 11A includes the 2-1 surface 112A forming the other outer surface of the substrate 1A and a 2-2 surface 113A on the side facing the first layer 10A. The first layer 10A and the second layer 11A are insulation layers made of an insulation material containing a ceramic material, respectively, as in the first layer 10 and the second layer 11 of the substrate 1 described above.

In the substrate 1A, the thickness of the first layer 10A and the second layer 11A and the diameter D1 of the first through hole 101A are the same as and/or similar to those in the substrate 1 described above. In the 2-1 surface 112A, the second through hole 111A has, for example, a circular shape, and has a diameter D2 of 100 μm or more and 200 μm or less.

With the second layer 11A arranged on the outer side of the package, the second through hole 111A one size larger than the first through hole 101A can be provided on the outer side of the fine first through hole 101A. Thus, the substrate 1A can have further improved waterproof property.

### First Through Hole

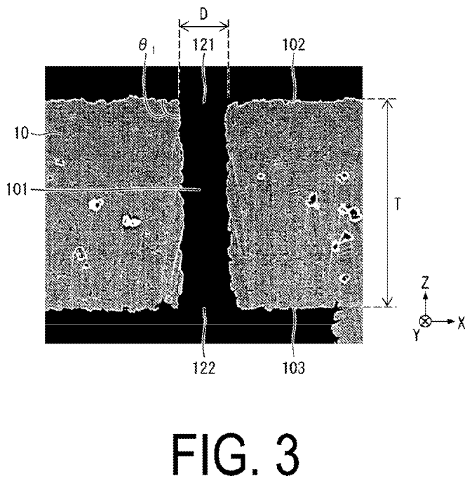

The first through hole 101 will be described in detail below with reference to FIGS. 3 to 10. It should be noted that the following description about the first through hole 101 is also applicable to the first through holes 101A described above and all the first through holes described hereinafter.

The sensor device configured using the substrate 1 includes a through hole through which gas passes, in order to secure breathability for the sensor element to be mounted inside. For example, waterproof property equivalent to the IPX7 level is required for the electronic apparatus in which the sensor element is mounted. Therefore, the first through hole 101 of the substrate 1 is desired to be configured such that good breathability and waterproof performance equivalent to the IPX7 level can be achieved. Under such circumstances, the present inventor intensively studied a substrate having a waterproof structure while securing good breathability, and come up with the substrate of the present disclosure.

FIG. 3 is an exemplary SEM photograph illustrating a cross-section of the first through hole 101 formed in the first layer 10 taken along a plane (X-Z plane) orthogonal to the surface of the first layer 10. As illustrated in FIG. 3, the first through hole 101 may be substantially orthogonal to the first layer 10. The first through hole 101 has a linear tubular shape, with the diameter of the first opening portion 121 on the 1-1 surface 102 side and the diameter of the second opening portion 122 on the 1-2 surface 103 side being substantially the same. More specifically, in the cross section illustrated in FIG. 3, the smaller angle (θ₁) of the angles between the line segment formed by the inner wall surface of the first through hole 101 and the line segment formed by the surface of the first layer 10 may be 80° and more and 90° or less. With the first through hole 101 configured as described above, good breathability can be achieved. Note that in the example illustrated in FIG. 3, the first layer 10 has a thickness T of approximately 100 μm, and the first through hole 101 has a diameter D on the 1-1 surface 102 side of approximately 26 μm.

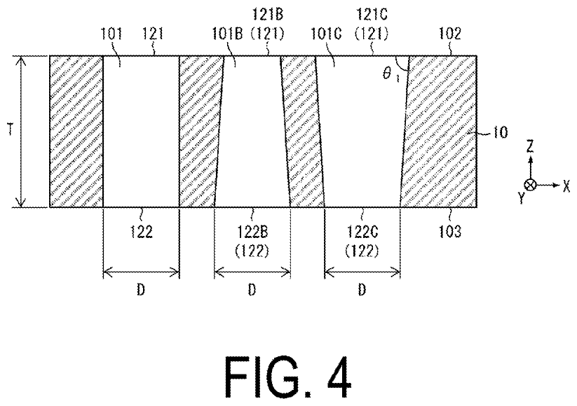

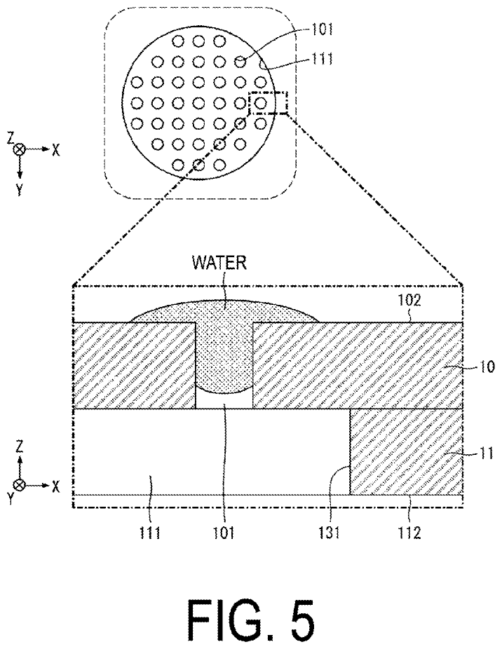

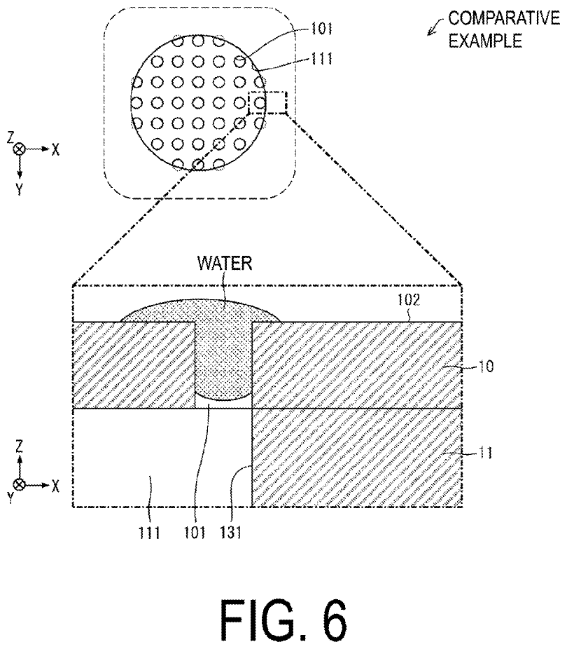

An aspect of the first through hole 101 for improving the waterproof property will be described with reference to FIGS. 4 to 6. FIG. 4 is a schematic cross-sectional view of the first layer 10, illustrating another aspect of the first through hole 101. FIG. 5 illustrates a plan view of the substrate 1 as viewed from the 2-1 surface 102 side and an enlarged cross-sectional view of the substrate 1 in a plane parallel to the X-Z plane. The plan view illustrates an example of the arrangement of the first through holes 101 relative to the second through hole 111. FIG. 6 illustrates a comparative example with respect to FIG. 5.

As illustrated in FIG. 4, in the first through hole 101, the size of the first opening portion 121 and the size of the second opening portion 122 may be different from each other. In FIG. 4, a first through hole 101B illustrates an example in which a first opening portion 121B is smaller than a second opening portion 122B. A first through hole 101C illustrates an example in which a first opening portion 121C is larger than a second opening portion 122C.

In FIG. 4, the first opening portion 121 side is assumed to be a side from which water may enter. Here, if the diameter of the first opening portion 121 is larger than the diameter of the second opening portion 122 as in the first through hole 101C, water may relatively easily enter the first through hole 101C from the 1-1 surface 102 side. On the other hand, if the diameter of the second opening portion 122 is larger than the diameter of the first opening portion 121 as in the first through hole 101B, the water that has entered the first through hole 101B from the 1-1 surface 102 side may easily flow out to the 1-2 surface 103. The greater the difference in diameter between the first opening portion 121 and the second opening portion 122, the more likely it is for the events as described above to occur.

In view of the above, in the first through hole 101, the smaller angle (θ₁) of the angles between the line segment formed by the inner wall surface of the first through hole 101 and the line segment formed by the surface of the first layer 10 may be 80° or more and 90° or less. The first through hole 101 may have a linear tubular shape with the first opening portion 121 and the second opening portion 122 having substantially the same diameter. The thickness T of the first layer 10 (in other words, the distance between the first opening portion 121 and the second opening portion 122 of the first through hole 101) may be larger than two times the diameter D of the first opening portion 121. With this configuration, the substrate 1 can have further improved waterproof property. With the first through holes 101 having a linear tubular shape, intervals between the holes can be made narrower. This can increase the number of first through holes 101 formed in the substrate 1, whereby breathability can be improved.

When the first through holes 101 are formed by etching a substrate made of silicon, the through holes are tapered, which makes it difficult to obtain a linear tubular shape with the first opening portion 121 and the second opening portion 122 having substantially the same diameter. On the other hand, in the present disclosure, the substrate 1 is a ceramic insulation layer, and thus the first through holes 101 having a linear tubular shape can be easily formed by punching a ceramic green sheet using a die or the like.

A slight difference in size between the two opening portions of the first through hole 101 may be tolerated. For example, when the diameter of the smaller opening portion is 10 μm or more and 50 μm or less as described above, the diameter of the larger opening portion may be 100 μm or less to achieve desired waterproof performance. The larger opening may be the side from which water may enter. That is, as in the first through hole 101C in FIG. 4, the through hole may have a tapered shape, with the first opening portion 121 being larger than the second opening portion 122. The first opening portion 121 has a certain degree of waterproof property as long as it is dimensioned to be 100 μm or less. Due to resistance of the air in the first through hole 101, the water entered is less likely to reach the second opening portion 122. With a certain degree of water pressure applied, the water entered may reach the second opening portion 122. However, the second opening portion 122 has a sufficiently small diameter, and thus the possibility of water entry beyond the second opening portion 122 can be reduced. Thus, in cases where the two opening portions of the first through hole 101 have different sizes, better waterproof property is achieved when the first opening portion 121 is larger than the second opening portion 122.

As illustrated in FIG. 5, the first through hole 101 may be formed away from the inner side surface of the second through hole 111 in plan view of the substrate 1 as viewed from the 2-1 surface 112 side of the second layer 11. With this configuration, a portion where water spreads can be secured around the first through holes 101 on the 1-1 surface 102, which makes it difficult for water to enter the first through holes 101 due to surface tension. In the comparative example illustrated in FIG. 6, the through holes are not away from the inner side surface of the second through hole 111, and thus water is likely to enter the through holes through the inner side surface of the second through hole 111. With the first through holes 101 formed away from the inner side surface of the second through hole 111, the possibility of water entry into the first through holes 101 can be further reduced.

In order to further improve the waterproof performance, a coating layer having a water-repellent function may be provided on one of the 1-1 surface 102 and the 1-2 surface 103 of the first layer or both. The coating layer having the water-repellent function can be formed by, for example, immersing the substrate 1 into a processing liquid containing fluorine and drying the processing liquid. The coating layer may also be formed on the inner wall of the first through hole 101 by applying pressure or reducing pressure during immersion in the processing liquid to allow the processing liquid to enter the first through hole 101. With the coating layer provided, water cannot easily enter the first through hole 101, and thus the hole diameter of the first through hole 101 can be increased as compared with a case where the coating layer is not provided. This can improve breathability.

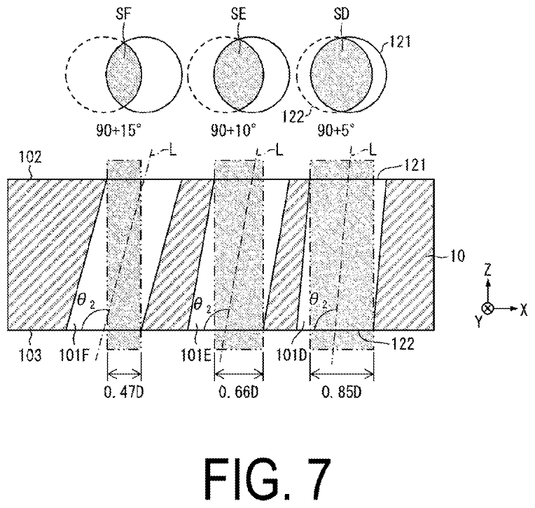

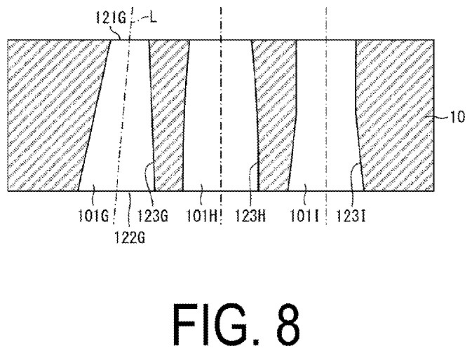

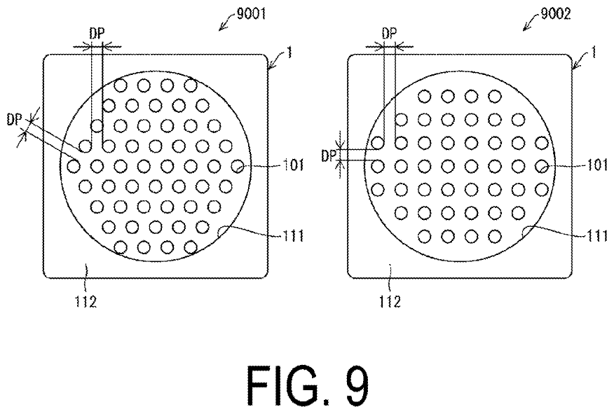

Next, an aspect of the first through hole 101 for the substrate 1 to have good breathability will be described with reference to FIG. 4 and FIGS. 7 to 10. FIG. 7 is a schematic cross-sectional view of the first layer 10 and a plan view of the first through holes 101 as viewed from the 1-1 surface 102 side of the first layer 10, illustrating another aspect of the first through holes 101. FIG. 8 is a schematic cross-sectional view of the first layer 10, illustrating another aspect of the first through hole 101. FIGS. 9 and 10 are schematic plan views of the substrate 1 as viewed from the 2-1 surface 112 side of the second layer 11, illustrating an example of an arrangement of the first through holes 101.

The first through holes 101 may be inclined with respect to the 1-1 surface 102 or the 1-2 surface 103 of the first layer 10 as in a first through hole 101D, a first through hole 101E, and a first through hole 101F as illustrated in FIG. 7. In FIG. 7, the first through hole 101D is an example in which a virtual center line L connecting the center of the first opening portion 121 and the center of the second opening portion 122 is inclined by 90°+5° (angle θ₂=95°) with respect to the 1-1 surface 102 or the 1-2 surface 103 of the first layer 10. When the diameter of the second opening portion 122 of the first through hole 101D is D, a length in the X axis direction of an overlapping region SD where the first opening portion 121 and the second opening portion 122 overlap each other in plan view is approximately 0.85 D. The first through hole 101E is an example in which the virtual center line L is inclined by 90°+10° (angle θ₂=100°) with respect to the 1-1 surface 102 or the 1-2 surface 103 of the first layer 10. When the diameter of the second opening portion 122 of the first through hole 101E is D, a length in the X axis direction of an overlapping region SE is approximately 0.66 D. The first through hole 101F is an example in which the virtual center line L is inclined by 90°+15° (angle θ₂=105°) with respect to a substrate surface. When the diameter of the second opening portion 122 of the first through hole 101F is D, a length in the X axis direction of an overlapping region SF is approximately 0.47 D.

For the first through holes 101 to achieve good breathability, a surface area of an overlapping region S (SD, SE, and SF in FIG. 7) in which the first opening portion 121 and the second opening portion 122 of the through hole overlap each other in plan view of the substrate 1 is preferably large. To secure desired breathability, the virtual center line L may be 90°±10° or less, or 90°±5° or less with respect to the 1-1 surface 102 or the 1-2 surface 103 of the first layer 10.

The first through hole 101 may be similar to a first through hole 101G, a first through hole 101H, or a first through hole 101I illustrated in FIG. 8. The first through hole 101G in FIG. 8 is an example in which a first opening portion 121G and a second opening portion 122G have different hole diameters and the virtual center line L is inclined with respect to the 1-1 surface 102 or the 1-2 surface 103 of the first layer 10. The first through hole 101H is an example in which an inner wall surface 123H of the first through hole 101H is a curved surface. The first through hole 101I is an example in which an inner wall surface 123I of the first through hole 101I is a bent surface. As in the first through hole 101H and the first through hole 101I, an inner wall surface 123 of the through hole may be gently curved or gently bent. As in the first through hole 101B and the first through hole 101C illustrated in FIG. 4, the size of the first opening portion 121 and the size of the second opening portion 122 may be different from each other.

On the other hand, when the inclination of the inner wall is large in the first through hole 101B illustrated in FIG. 4 and the first through hole 101G illustrated in FIG. 8, breathability may decrease. When the curve of the inner wall surface 123H of the first through hole 101H and the bend of the inner wall surface 123I of the first through hole 101I illustrated in FIG. 8 are to a large degree, breathability may decrease.

From the above, for the sake of waterproof property and breathability, the first through hole 101 may have a straight cylindrical shape extending in a direction substantially orthogonal to the first layer 10, with the hole diameter of the first opening portion 121 and the hole diameter of the second opening portion 122 being substantially the same.

Next, an exemplary arrangement of the first through holes 101 in the first layer 10 will be described with reference to FIGS. 9 and 10. The arrangement of the first through holes 101 in the first layer 10 is not particularly limited. Any arrangement can be selected in accordance with the type and characteristics of the sensor element to be mounted. Reference sign 9001 in FIG. 9 illustrates an example in which the first through holes 101 have a staggered arrangement in plan view of the substrate 1 as viewed from the 2-1 surface 112 side of the second layer 11. Reference sign 9002 in FIG. 9 illustrates an example in which the first through holes 101 have a lattice arrangement.

An inter-hole distance DP between the first through holes 101 is the same between the staggered arrangement of reference sign 9001 and the lattice arrangement of reference sign 9002. On the other hand, when comparing the staggered arrangement of reference sign 9001 and the lattice arrangement of reference sign 9002, the number of first through holes 101 included in the second through hole 111 is larger in the staggered arrangement of reference sign 9001. In other words, with the staggered arrangement, a larger number of the first through holes 101 having the same diameter can be arranged in a region having the same surface area than with the lattice arrangement having the same inter-hole distance DP. To achieve good breathability, a ratio of the sum of the areas of the hole portions of the first through holes 101 to the area of the hole portion of the second through hole 111 is preferably higher. Thus, the larger the number of first through holes 101 included within the second through hole 111, the better. Since the distance DP between the first through holes 101 is the same, even when the number of first through holes 101 is increased due to the employment of the staggered arrangement, influence on the strength of the substrate 1 is considered to be low. From the above, for the sake of breathability, the first through holes 101 may be arranged in a staggered arrangement. With the plurality of first through holes 101 arranged in a staggered arrangement, breathability of the substrate 1 can be improved.

FIG. 10 illustrates an example in which the first layer 10 does not include the first through hole 101 at the central portion. With this configuration, when the sensing portion of the sensor element is arranged immediately below the central portion of the substrate 1, the possibility of dust or water droplets that have passed through the first through holes 101 affecting the sensing portion can be reduced.

### Demonstration Test 1: Waterproof Test 1

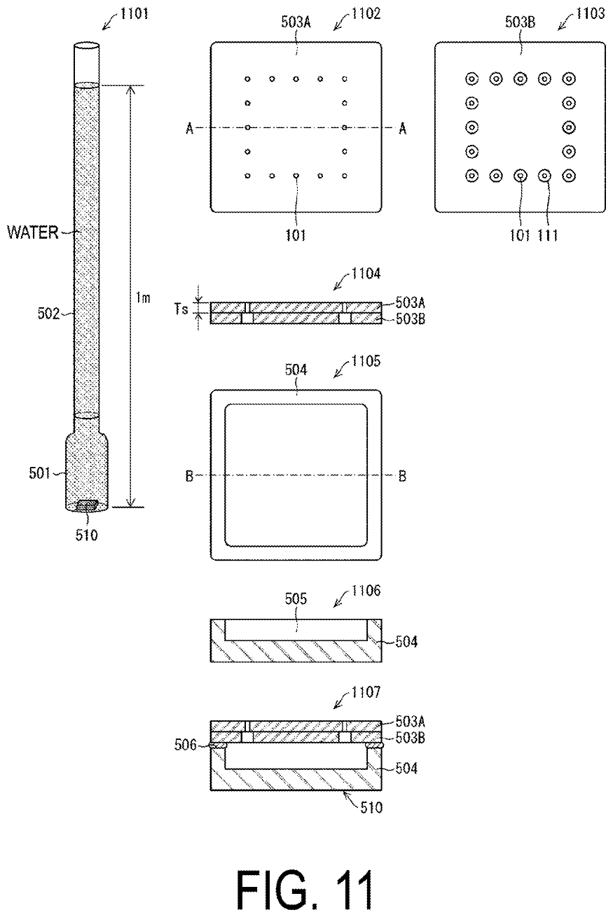

Hereinafter, a waterproof test will be described with reference to FIG. 11. In the waterproof test, the diameter D1 of the first through hole 101 and a thickness Ts of the through hole were variously changed to examine whether water entry occurs upon being subjected to water pressure at a water depth of 1 m for 30 minutes. FIG. 11 is a view illustrating an outline of a device used in the waterproof test. When no water entry occurs while an evaluation sample 510 is submerged for 30 minutes in a state in which a distance from an upper surface of the evaluation sample 510 to water surface is 1 m, the evaluation sample 510 can be determined to have the waterproof performance of the IPX7 level.

FIG. 11 is a schematic view illustrating the device used in the waterproof test. Reference sign 1101 in FIG. 11 denotes an overall view of the device used in the waterproof test. The evaluation sample 510 was installed at a bottom portion of the device in which a sample bottle 501 and a circular tube 502 were connected to each other. The 30-minute waterproof test was conducted in a state where the inside of a container was filled with water so that the height from an upper surface of the evaluation sample 510 to the water surface was 1 m. In the evaluation sample 510, a sample substrate (an upper layer 503A and lower layer 503B) and a cavity substrate 504 were bonded to each other using a resin adhesive 506. Reference sign 1102 in FIG. 11 denotes a top view of the sample substrate of the evaluation sample 510, and reference sign 1103 denotes a bottom view of the sample substrate of the evaluation sample 510. Reference sign 1104 denotes a cross-sectional view taken along a line A-A of reference sign 1102. The sample substrate included two layers. The first through holes 101 were formed in the upper layer 503A, which was in contact with water. The thickness of the upper layer 503A is, in other words, the thickness Ts of the through hole. The second through hole 111 having a larger hole diameter than that of the first through hole 101 was formed in the lower layer 503B at a position corresponding to the first through hole 101.

Reference 1105 is a top view of the cavity substrate 504, and reference sign 1106 denotes a cross-sectional view taken along a line B-B of reference sign 1105. Reference sign 1107 denotes a cross-sectional view of the evaluation sample 510.

Each of the upper layer 503A, the lower layer 503B, and the cavity substrate 504 of the evaluation sample 510 was fabricated using an alumina-based sintered body without coating. Surface roughness Ra of the upper layer 503A, the lower layer 503B, and the cavity substrate 504 was less than 2.0 μm. The wetting angles of water at the upper layer 503A, the lower layer 503B, and a surface of the cavity substrate 504 were less than 90°.

After a test time of 30 minutes, the sample substrate was removed from the cavity substrate 504, and then occurrence of water entry into the cavity 505 was checked using a 10-power microscope. Each example was evaluated using 20 evaluation samples. For the through holes having the hole diameter of 0.051 mm and the through hole thickness of 0.1 mm, a test was similarly conducted using 10 evaluation samples as a comparative example.

Table 1 is a correspondence table between the hole diameters and the through hole thicknesses of the tested evaluation samples for the examples.

TABLE 1

| | | Through hole thickness (Ts) [mm] | | | | |
|---|---|---|---|---|---|---|
| | | 0.076 | 0.089 | 0.100 | 0.114 | 0.127 |
| Hole diameter | Φ0.026 | Good | Good | Good | | |
| (D) [mm] | Φ0.034 | | Good | Good | Good | |
| | Φ0.042 | | | Good | Good | Good |

Table 2 is a table showing results of the waterproof test of the evaluation samples shown in Table 1 and a comparative example. Each of examples 1 to 9 in Table 2 corresponds to any of the good marks in Table 1.

TABLE 2

| | Examples | | | | | | | | | Comparative |
|---|---|---|---|---|---|---|---|---|---|---|
| | 1 | 2 | 3 | 4 | 5 | 6 | 7 | 8 | 9 | Example |
| Hole diameter [mm] | 0.026 | | | 0.034 | | | 0.042 | | | 0.051 |
| Through hole | 0.076 | 0.089 | 0.100 | 0.089 | 0.100 | 0.114 | 0.100 | 0.114 | 0.127 | 0.100 |
| thickness (Ts) [mm] | | | | | | | | | | |
| Number of samples | 0/20 | 0/20 | 0/20 | 10/20 | 0/20 | 0/20 | 0/20 | 0/20 | 0/20 | 2/10 |
| with water entry (n = | | | | | | | | | | |
| 20) | | | | | | | | | | |

As shown in Table 2, no water entry from the first through holes 101 was observed in any of examples 1 to 9. In other words, all of examples 1 to 9 were demonstrated to have the waterproof property of the IPX 7 level. For the comparative example, water entry was observed in two evaluation samples out of 10 evaluation samples.

### Demonstration Test 2: Waterproof Test 2

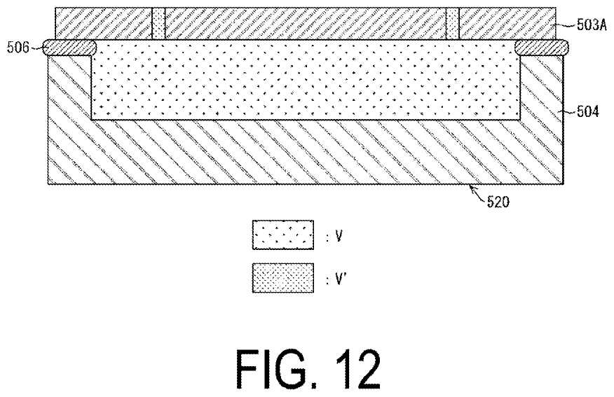

Hereinafter, a waterproof test 2 will be described with reference to FIG. 12. The waterproof test 2 examined a relationship between the waterproof performance and a ratio (V′/V) of a total volume V′ of the first through holes 101 having waterproof effect to a spatial volume V in a package communicating with the first through holes 101. FIG. 12 is a cross-sectional view of an evaluation sample 520 used in the waterproof test 2.

The evaluation sample 520 used in the waterproof test 2 is different from the evaluation sample 510 used in the waterproof test 1 in that the lower layer 503B was not provided. The other configurations are the same as those of the evaluation sample 510.

As illustrated in FIG. 12, the total volume of the first through holes 101 of the evaluation sample 520 is defined as V′, and the spatial volume defined by the lower surface of the upper layer 503A and the inner surface of the cavity substrate 504 is defined as V. As a sample A, the evaluation sample 520 was prepared that included the upper layer 503A having a size of 2.8 mm×2.8 mm in plan view on the cavity substrate 504 having a size of 3.0 mm×3.0 mm×1.1 mm. As a sample B, the evaluation sample 520 was prepared that included the upper layer 503A having a size of 1.9 mm×1.9 mm in plan view on the cavity substrate 504 having a size of 2.05 mm×2.05 mm×0.9 mm. The thickness of the upper layer 503A was 0.1 mm in both the sample A and the sample B. The upper layer 503A included 16 first through holes 101 having a hole diameter of 0.034 mm.

For the sample A, V′/V was calculated to be 0.05%. On the other hand, for the sample B, V′/V was calculated to be 0.12%.

For the waterproof test 2 as well, the device denoted by reference sign 1101 in FIG. 11 was used. When no water entry occurs while the evaluation sample 520 is submerged for 30 minutes in a state in which a distance from an upper surface of the evaluation sample 520 to water surface is 1 m, the evaluation sample 520 can be determined to have the waterproof performance of the IPX7 level. Similarly, when no water entry occurs while the evaluation sample 520 is submerged for 30 minutes in a state in which a distance from an upper surface of the evaluation sample 520 to water surface is 1.5 m, the evaluation sample 520 can be determined to have the waterproof performance of the IPX8 level.

Table 3 is a table showing results of the waterproof test 2 with the sample A and the sample B.

TABLE 3

| | Sample A | Sample B |
|---|---|---|
| 1 m/30 min | 0/20 | 0/10 |
| 1.5 m/30 min | 11/20 | 0/10 |

After a test time of 30 minutes, the upper layer 503A was removed from the cavity substrate 504, and then occurrence of water entry into the cavity was checked using a 10-power microscope. The evaluation was performed using 20 evaluation samples for sample A and 10 evaluation samples for sample B.

As shown in Table 3, for the sample A, no water entry was observed in any of the 20 evaluation samples under the 1 m/30 minutes test, and thus the sample A was demonstrated to have the waterproof property of the IPX7 level. However, water entry was observed in 11 out of 20 evaluation samples under the 1.5 m/30 minutes test. On the other hand, for the sample B, no water entry was observed in any of the 10 evaluation samples under the 1 m/30 minutes test for satisfying the IPX7 requirement and the 1.5 m/30 minutes test for satisfying the IPX8 requirement. Thus, the sample B was demonstrated to have the waterproof property of the IPX7 level and the IPX8 level.

From the above, it was demonstrated that the higher the V′/V, the higher the waterproof property. Since the waterproof property of the IPX8 level was demonstrated, the condition of V′/V>0.1% may be satisfied.

### Second Embodiment

Another embodiment of the present disclosure will be described below. For convenience of description, a member having the same function as that of a member described in the embodiments described above is denoted by the same reference sign, and description thereof will not be repeated. The same applies to the following embodiments.

In the present embodiment, a gas sensor device 200 (sensor device) will be described in which the package 100 including the substrate 1 described in the first embodiment is mounted with a gas sensor element 3G (sensor element) as an example of a sensor element 3. While the gas sensor device 200 with the gas sensor element 3G mounted therein will be described in a second embodiment, the sensor element to be mounted is not limited to the gas sensor element 3G. The configuration of the gas sensor device 200 illustrated as an example in the second embodiment may be applied to sensor devices in which a sensor element is mounted that requires that the package to be mounted with the sensor element have breathability. The sensor element is, for example, a gas sensor element that detects a property of a gas. More specifically, the sensor element may be a gas sensor element, an atmospheric pressure sensor element, a humidity sensor element, or the like.

### Configuration of Gas Sensor Device 200

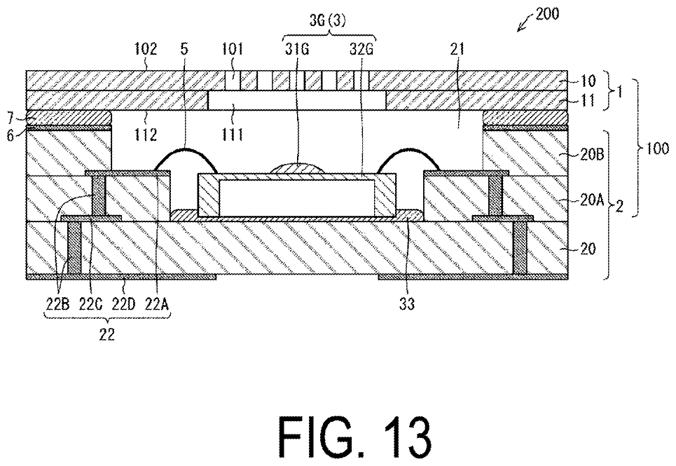

FIG. 13 is a cross-sectional view of the gas sensor device 200. The gas sensor device 200 includes the package 100 and the gas sensor element 3G. The package 100 includes the substrate 1 (second substrate) and a wiring board 2 (first substrate) including an accommodation recess 21 and wiring conductors 22, the accommodation recess 21 being configured to accommodate a sensor element. The substrate 1 is a lid body of the package 100. The gas sensor device 200 (package 100) may have, for example, a quadrangular shape such as a rectangular shape or a square shape in plan view.

The substrate 1 is as described in the first embodiment. In the gas sensor device 200 illustrated in FIG. 13, the substrate 1 is arranged with the 1-1 surface 102 forming part of the outer surface of the package 100 and with the 2-1 surface 112 facing the gas sensor element 3G.

The wiring board 2 is a substrate on which the gas sensor element 3G is mounted. The wiring board 2 has functions of securing mechanical strength as the substrate for mounting the gas sensor element 3G, securing insulation property between the plurality of wiring conductors 22, and the like. The accommodation recess 21 of the wiring board 2 may have any shape and any size as long as the gas sensor element 3G can be accommodated therein. The shape of the inner side surface of the accommodation recess 21 is not particularly limited either. As illustrated in FIG. 13, the inner side surface of the accommodation recess 21 may have a stepped shape. The inner side surface may be an inclined surface inclined with respect to the bottom surface of the wiring board 2. The wiring board 2 includes the wiring conductors 22 provided in an inner portion and on a surface thereof.

The wiring board 2 may be a laminate body in which a plurality of insulation layers made of, for example, an aluminum oxide-based sintered body are layered on one another.

The wiring conductors 22 are provided on the surface and in an inner portion of the wiring board 2. For example, as illustrated in FIG. 13, the wiring board 2 includes, as the wiring conductors 22, connection pads 22A for connection to the gas sensor element 3G, and terminal electrodes 22D for connection to an external electrical circuit. The connection pads 22A are each electrically connected to a respective one of the terminal electrodes 22D using the through-hole conductors 22B and an internal wiring layer 22C provided in the inner portion of the wiring board 2. The through-hole conductors 22B extend through the insulation layers, and the internal wiring layer 22C is arranged between the insulation layers. The terminal electrode 22D may be provided not only at the lower surface but also from the lower surface to the side surface or on the side surface of the wiring board 2.

The wiring conductors 22 mainly contain, for example, metal such as tungsten, molybdenum, manganese, copper, silver, palladium, gold, platinum, nickel, and cobalt, or an alloy containing any of these metals as a conductor material. The connection pad 22A and the terminal electrode 22D are formed on the surface of the wiring board 2 as a metal layer such as a metallized layer or plating layer of the conductor material. The metal layer may be a single layer, or a plurality of layers. The through-hole conductors 22B and the internal wiring layer 22C are formed in the inner portion of the wiring board 2 by metallization of the conductor material.

In a case where the connection pad 22A, the internal wiring layer 22C, and the terminal electrode 22D of the wiring conductors 22 are, for example, a metallized layer of tungsten, these components can be formed as follows. Specifically, these components can be formed by a method in which a metal paste produced by mixing powder of tungsten with an organic solvent and an organic binder is printed at a predetermined position of the ceramic green sheet to be the wiring board 2 using a method such as a screen printing method and then fired. A plating layer of nickel, gold, or the like may be further deposited on an exposed surface of the metallized layers to serve as the connection pad 22A and the terminal electrode 22D among the above-described components using electrolytic plating method, electroless plating method, or the like. The through-hole conductors 22B may be formed by providing a through hole at a predetermined position of the ceramic green sheet prior to printing the metal paste described above, filling the through hole with the metal paste described above, and firing the metal paste.

The substrate 1 and the wiring board 2 may be bonded to each other via sealing bonding material 7. Examples of the sealing bonding material 7 include, resin adhesives, glass, and brazing material including solder. When the substrate 1 and the wiring board 2 are bonded to each other using brazing material, a bonding metal layer 6 may be provided on the upper surface of the wiring board 2 and at a portion of the substrate 1 facing the upper surface of the wiring board 2. The bonding metal layer 6 may be made of, for example, a metal film such as a plating film or a metallized layer.

As the gas sensor element 3G, for example, a substrate semiconductor-type gas sensor is used. The substrate semiconductor-type gas sensor is obtained by forming a thin film or a thick film of a semiconductor material serving as a gas sensing portion 31G on a surface of a support substrate 32G, and then firing the thin film or thick film. Comb-shaped platinum electrodes (not illustrated) are provided on the surface of the support substrate 32G, and a sensor output is obtained using a platinum wire wired between the electrodes as a signal wire. The gas sensing portion 31G is heated using a platinum heater (not illustrated) on the back side of the support substrate 32G. The gas sensor element 3G may be a MEMS-type semiconductor-based gas sensor using, as the support substrate, a MEMS substrate having a diaphragm structure and having a heater incorporated therein. For example, the lower surface of the gas sensor element 3G is bonded and fixed to the bottom surface of the accommodation recess 21 of the wiring board 2 using a bonding material 33. An electrode (not illustrated) arranged on the upper surface of the gas sensor element 3G, and the wiring board 2 are electrically connected to each other by a connecting member 5.

Generally, the gas sensing portion 31G detects gas in a state of being heated to a temperature of approximately 200° C. to 500° C. by the heater, but this varies depending on the types of gas detected. Therefore, the package containing the gas sensor element 3G is advisably made of a material that is unlikely to generate gas or corrode even when exposed to high temperatures. Ceramic is less susceptible to corrosion by various gases or moisture. Even when exposed to high temperatures, ceramic itself generates very little gas. From these viewpoints, ceramic is an excellent material for the package or the substrate of the gas sensor device 200.

In the gas sensor device 200, the terminal electrode 22D and the external electrical circuit are electrically connected to each other, and thus the gas sensor element 3G mounted on the wiring board 2 (package 100) and the external electrical circuit are electrically connected to each other. In other words, the gas sensor element 3G and the external electrical circuit are electrically connected via the connecting member 5 such as a bonding wire, and the wiring conductors 22. The external electrical circuit is, for example, an electrical circuit included in a mounting substrate (circuit board) mounted in an electronic apparatus such as a smartphone.

### Package 100

The package 100 includes the wiring board 2 including the accommodation recess 21 that accommodates the gas sensor element 3G, and the substrate 1 that closes the accommodation recess 21. The substrate 1 includes: the first layer 10 that is a ceramic insulation layer including the plurality of first through holes 101; and the second layer 11 that is a ceramic insulation layer including at least one second through hole 111. The diameter of the first through hole 101 is from 10 μm to 50 μm, and the diameter of the second through hole 111 is larger than the diameter of the first through hole 101. At least some of the plurality of first through holes 101 overlap the second through hole 111 in plan view of the first layer 10, and the second layer 11 is located on the accommodation recess 21 side.

With the configuration described above, the package with breathability and waterproof property can be obtained. It also becomes easier for gas that has passed through the first through hole 101 to further pass through the second through hole 111 and flow toward the gas sensing portion 31G of the gas sensor element 3G. Thus, sensor sensitivity can be improved.

In the package 100, the diameter of the second through hole 111 (or the length of one side in the case of a quadrangle) may be ½ of the diameter (or the length of one side) of the gas sensor element 3G or more, and twice the diameter (or the length of one side) or less. For example, when the diameter (or one side) of the gas sensor element 3G is 1 mm, the second through hole 111 may have a circular shape with a diameter of 0.5 mm or more and 2 mm or less, or a polygonal shape with one side being 0.5 mm or more and 2 mm or less. With this configuration, a protruding portion (gas sensing portion 31G) of the gas sensor element 3G can be accommodated in a recessed portion of the substrate 1 formed by the second through hole 111, so that the thickness can be further reduced. When the gas sensor element 3G is connected by wire bonding, the apex portion of the loop of the connecting member 5 (bonding wire) can be accommodated in the recessed portion formed by the second through hole 111. In this case as well, the package 100 and the gas sensor device 200 can be reduced in thickness. The gas sensing portion 31G can be arranged at a position close to the outer surface of the package 100. The air risen as a result of being heated in the gas sensing portion 31G is likely to accumulate in the second through hole (recessed portion of the substrate), and thus discharge of the heated air is facilitated. Accordingly, more air outside the package can be taken in. This improves gas sensing sensitivity.

### Variation 2-1

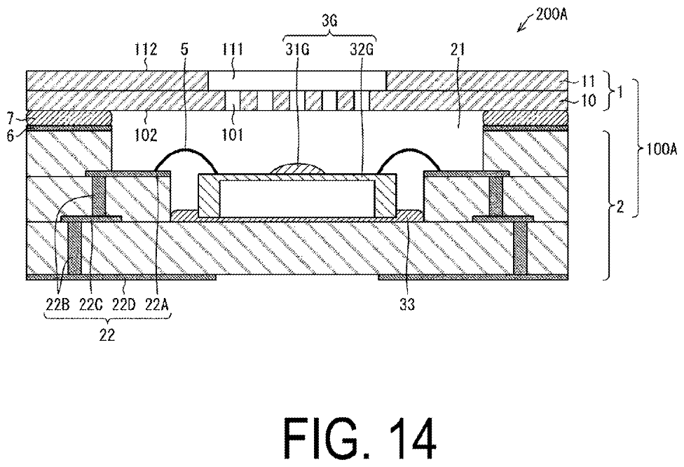

FIG. 14 is a cross-sectional view of another exemplary gas sensor device 200A according to the second embodiment. The gas sensor device 200A includes a package 100A and the gas sensor element 3G. The package 100A includes the substrate 1 according to the first embodiment and the wiring board 2 according to the second embodiment. The package 100A is different from the package 100 of the second embodiment described above in the orientation of the substrate 1. Specifically, as illustrated in FIG. 14, in the substrate 1 of the gas sensor device 200A, the 2-1 surface 112 forms part of the outer surface of the package 100A, and the 1-1 surface 102 faces the gas sensor element 3G. That is, as in the variation 2-1, the first layer 10 may be located on the accommodation recess 21 side. The gas sensor device 200A is the same as and/or similar to the gas sensor device 200 in FIG. 13 in other respects.

With the configuration described above, the surface of the first layer 10 is less likely to be subjected to mechanical contact from the outside, in a device conveying or assembling process. Thus, the possibility that the thin plate portion in which the first through hole 101 is formed in the substrate 1 is damaged by mechanical contact from the outside can be reduced.

### Variation 2-2

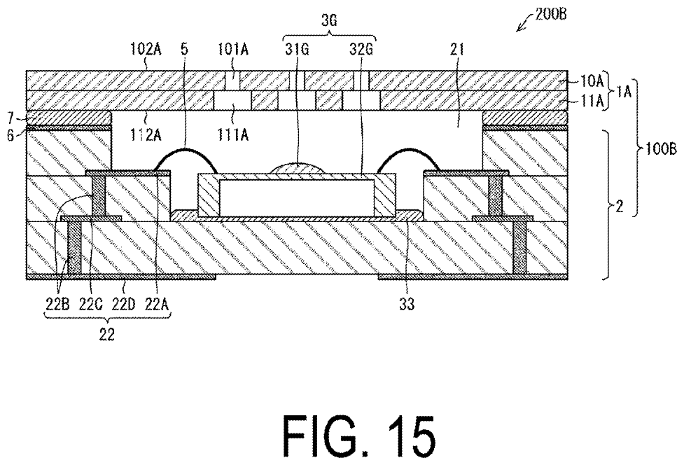

FIG. 15 is a cross-sectional view of another exemplary gas sensor device 200B according to the second embodiment. The gas sensor device 200B includes a package 100B and the gas sensor element 3G. The package 100B includes the substrate 1A according to the variation 1-1 of the first embodiment and the wiring board 2 according to the second embodiment.

The second through hole 111A is approximately one size larger than the fine first through hole 101A. As compared with the example described in the variation 2-1, in the example illustrated in the variation 2-2, the size of the second through hole 111A is small, whereby the package can have improved strength. Since the example illustrated in the variation 2-2 has excellent strength, the thickness can be further reduced.

### Variation 2-3

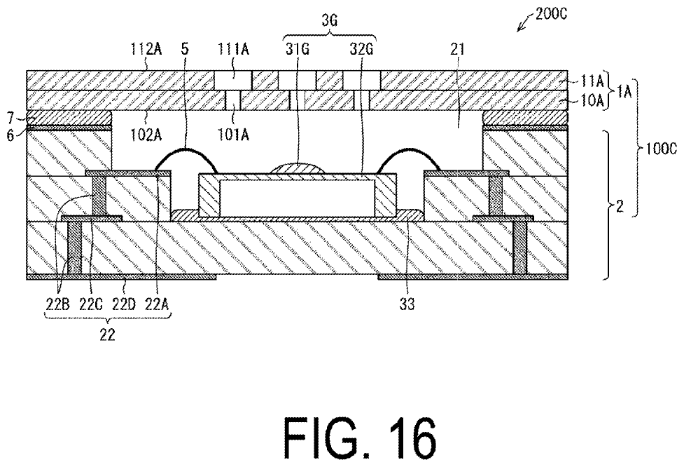

FIG. 16 is a cross-sectional view of another exemplary gas sensor device 200C according to the second embodiment. The gas sensor device 200C includes a package 100C and the gas sensor element 3G. The package 100C is different from the package 100B of the variation 2-2 described above in the orientation of the substrate 1A. Specifically, as illustrated in FIG. 16, in the substrate 1A of the gas sensor device 200C, the 2-1 surface 112A forms part of the outer surface of the package 100A, and the 1-1 surface 102A faces the gas sensor element 3G. The gas sensor device 200C is the same as and/or similar to the gas sensor device 200B in FIG. 15 in other respects.

In the configuration of the variation 2-3, the 2-1 surface 112A forms part of the outer surface of the package 100C, and the 1-1 surface 102A forms part of the inner surface of the package 100C. With the second through hole 111A that has a diameter of 100 μm or more and 200 μm or less provided on the outer side of the first through holes 101A that has a diameter of 10 μm or more and 50 μm or less and has excellent waterproof effect, a stepwise waterproof structure is obtained, whereby the waterproof effect can be further improved. Waterproofing by the fine first through holes 101 is mainly due to surface tension of water. When the second through hole 111A is also fine as described above, the second through hole 111A similarly has waterproof property due to surface tension. Therefore, a two-step waterproof structure is obtained by the second through hole 111A and the first through hole 101A. When the depth of water immediately after submersion is small (the water pressure is low), the second through hole 111A can keep water from entering. As the depth of water increases and thus the water pressure increases, water enters the first through holes 101A. However, the first through holes 101A that are finer and have higher waterproof property can keep water from entering. Further, the configuration of the variation 2-3 provides effects of reducing the possibility of damaging the thin plate portion described in the variation 2-1 and the variation 2-2, and improving the strength.

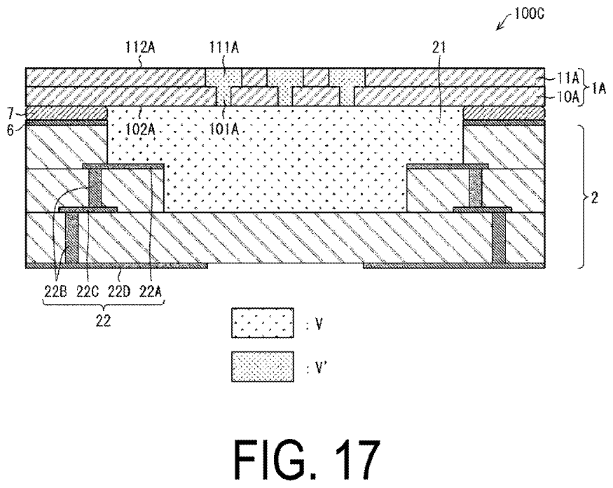

FIG. 17 is a cross-sectional view of the package 100C. The relationship between the spatial volume V in the package and the sum V′ of volumes of the first through holes 101A and the second through hole 111A will be described with reference to FIG. 17. As illustrated in FIG. 17, in the package 100C, the spatial volume V in the package is defined by the 1-1 surface 102A and the accommodation recess 21. When the space inside the package does not communicate with the outside through a route other than the first through holes 101A and the second through hole 111A of the substrate 1A, water from the outside can only enter by pushing the air from the second through hole 111A to the space inside the package. When the diameter of the second through hole 111A is also fine, water from the outside covers the opening of the second through hole 111A, and thus pushes the air in the second through hole 111A in order to enter. To enter the space in the package through the first through holes 101A, water further needs to push in the air in the first through holes 101A. The first through holes 101A and the second through hole 111A communicate with the space inside the package. The space inside the package does not communicate with the outside through a route other than the first through holes 101A and the second through hole 111A. Thus, water entering from the outside enters while compressing the air in the second through hole 111A, the first through holes 101A, and the space inside the package. Water from the outside needs to compress the air corresponding to the sum V′ of volumes of the second through hole 111A and the first through holes 101A, to enter the space inside the package. Thus, waterproofing by the substrate 1A is based on the repulsive force against compression of air in the entry route, in addition to the surface tension of water. The volume of air that needs to be compressed by water is the sum V′ of volumes of the second through hole 111A and the first through holes 101A. The larger the volume V′, the more difficult it is for water to enter. When the volume V′ of the air that needs to be compressed is large to a certain extent relative to the entire volume from the second through hole 111A to the space inside the package, water cannot easily enter the space inside the package. More specifically, the ratio of the sum V′ of the volumes of the second through hole 111A and the first through holes 101A to the volume V of the space inside the package is greater than 0.05% to be effective. Thus, satisfying the condition of V′/V≥0.05% can significantly reduce the possibility of water entry from the outside of the package 100C.

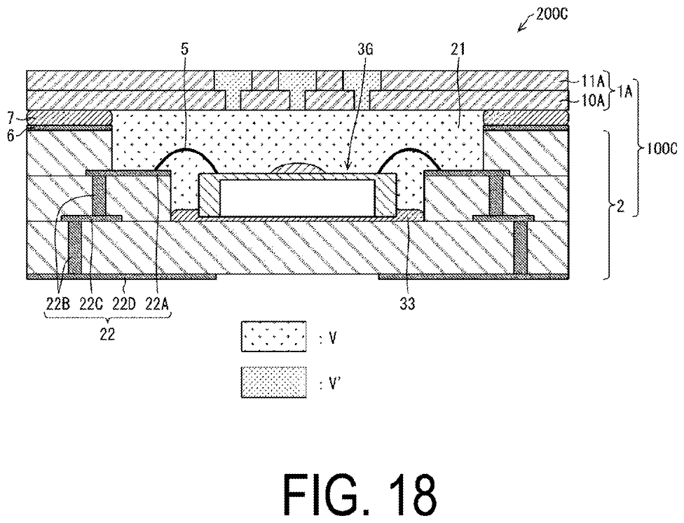

Here, a case where the gas sensor element 3G is mounted on the package 100C will be described. FIG. 18 is a cross-sectional view of the gas sensor device 200C. When the gas sensor element 3G is mounted on the wiring board 2 using resin or the like with no gaps formed, the spatial volume V in the package communicating with the first through holes 101A is defined by the 1-1 surface 102A, the accommodation recess 21, and the outer surface of the gas sensor element 3G as illustrated in FIG. 18. This reduces the spatial volume V in the package by the volume of the gas sensor element 3G, and thus the ratio of the sum V′ of volumes of the second through hole 111A and the first through holes 101A to the spatial volume V in the package exceeds 0.05% described above. More specifically, this ratio is higher than 0.3% to be more effective. Thus, with the gas sensor device 200C illustrated in FIG. 18, satisfying the condition of V′/V≥0.3% can significantly reduce the possibility of water entry from the outside of the gas sensor device 200C.

### Variation 2-4

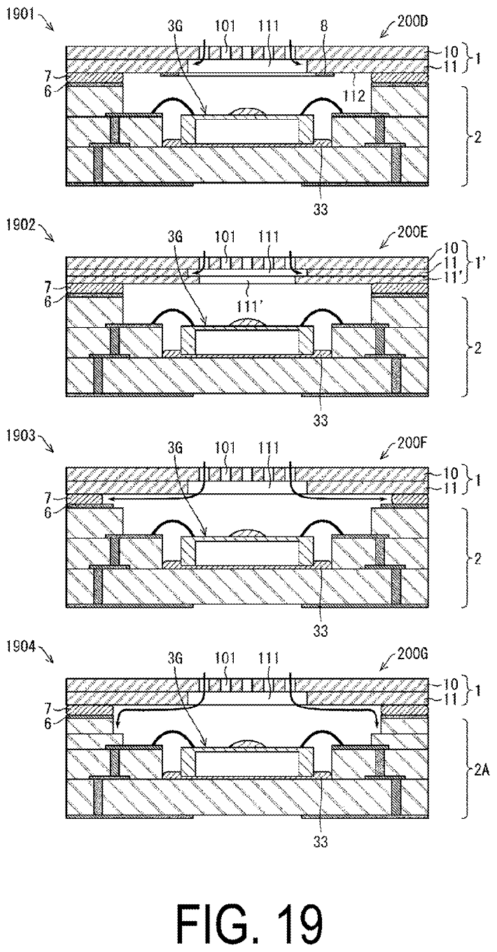

In a variation 2-4, an additional configuration that reduces, upon water entry through the first through holes 101, the possibility of the entered water reaching the gas sensor element 3G will be described with reference to FIG. 19.

FIG. 19 illustrates cross-sectional views of gas sensor devices 200D, 200E, 200F, and 200G. The gas sensor device 200D denoted by reference sign 1901 in FIG. 19 includes, on the 2-1 surface 112 of the gas sensor device 200 (FIG. 13) according to the second embodiment, a frame-shaped protrusion 8 along an outer edge portion of the second through hole 111 at a position spaced apart from the outer edge portion. The frame-shaped protrusion 8 may be a metallized layer or a ceramic layer. The frame-shaped protrusion 8 can be formed by applying a metal paste or a ceramic paste containing the same ceramic material as the ceramic of the substrate, on the ceramic green sheet. As illustrated in the view denoted by reference sign 1901 in FIG. 19, a step may be formed in the water entry route by providing the frame-shaped protrusion 8. This can reduce the possibility of water that has entered along the inner walls of the first through hole 101 and the second through hole 111 flowing toward the gas sensor element 3G.

The gas sensor device 200E denoted by reference sign 1902 in FIG. 19 is different from the gas sensor device 200 (FIG. 13) according to the second embodiment in that a second layer 11′ is further layered on the second layer 11 side of the substrate 1 of the gas sensor device 200. The second layer 11′ includes a second through hole 111′ dimensioned to be one size smaller than the second through hole 111 of the second layer 11. In other words, the second through hole 111′ (inner wall thereof) of the second layer 11′ is positioned on the inner side (inner wall) of the second through hole 111 of the second layer 11 in perspective plan view. This configuration can be regarded as a configuration in which the second layer includes the second layer 11′ forming the outer surface of the substrate 1, and the second layer 11 between the second layer 11′ and the first layer 10. The second through hole can also be regarded as a through hole that includes the second through hole 111′ of the second layer 11′ and the second through hole 111 of the second layer 11 one size larger than the second through hole 111′, and that has different dimensions in the thickness direction. As illustrated in the view denoted by reference sign 1902 in FIG. 19, a step may be formed in the water entry route by the layering of the second layer 11 and the second layer 11′. This can reduce the possibility of water that has entered along the inner wall of the first through hole 101 flowing toward the gas sensor element 3G. A frame-shaped protrusion surrounding the second through hole 111′ may be provided on a surface of the second layer 11′ on the first layer 10 side. This can reduce the possibility of water that has entered the second through hole 111 of the second layer 11 positioned in the middle in the thickness direction of a substrate 1′ entering the second through hole 111′ of the second layer 11′. This frame-shaped protrusion can be provided using a method that is the same as and/or similar to that for the frame-shaped protrusion 8 of the gas sensor device 200D. Alternatively, the frame-shaped protrusion may be provided, when forming the through hole to be the second through hole 111′ in the green sheet to be the second layer 11′ or when layering the green sheet with the through hole formed therein, by deforming the periphery of the through hole in a direction toward the first through hole 101 or in a like manner.

The gas sensor device 200F denoted by reference sign 1903 in FIG. 19 is different from the gas sensor device 200 (FIG. 13) according to the second embodiment in the shape of the sealing bonding material 7. Specifically, the inner circumferences of the bonding metal layer 6 and the sealing bonding material 7 are positioned on the outer side of the outer edge of the accommodation recess. Thus, a step is formed between the bonding metal layer 6 and the sealing bonding material 7 on the one hand, and the wiring board 2 on the other. As illustrated in the view denoted by reference sign 1903 in FIG. 19, the sealing bonding material 7 and the bonding metal layer 6 may form a step in the water entry route. This can reduce the possibility of water that has entered along the inner walls of the first through hole 101 and the second through hole 111 flowing toward the gas sensor element 3G.

A wiring board 2A of the gas sensor device 200G denoted by reference sign 1904 in FIG. 19 is different from the gas sensor device 200 (FIG. 13) according to the second embodiment in that a step is further formed on the inner wall surface of the wiring board 2 of the gas sensor device 200. With the step formed on the inner wall surface of the wiring board 2A as illustrated in the view denoted by reference sign 1904 in FIG. 19, the possibility of water that has entered along the inner walls of the first through hole 101 and the second through hole 111 flowing toward the gas sensor element 3G can be reduced.

### Variation 2-5

In a variation 2-5, an example where a plurality of sensor elements are mounted in a package, and a sensor device mounted with an IC chip such as an application specific integrated circuit (ASIC), a capacitor, and/or the like will be described.

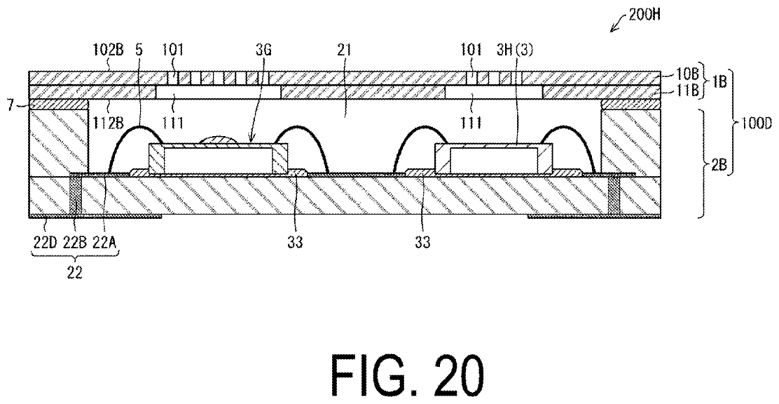

FIG. 20 is a cross-sectional view of a sensor device 200H. The sensor device 200H includes a package 100D, the gas sensor element 3G, and an atmospheric pressure sensor element 3H. The package 100D includes a substrate 1B, and a wiring board 2B including the accommodation recess 21 and the wiring conductor 22.

The substrate 1B includes a second layer 11B. The second layer 11B is provided with the second through holes 111 at positions corresponding to the gas sensor element 3G and the atmospheric pressure sensor element 3H, for example. A first layer 10B includes the plurality of first through holes 101 in each second through hole 111 in plan view of the substrate 1B as viewed from 2-1 surface 112B side. In the substrate 1B, a 1-1 surface 102B forms part of the outer surface of the package 100D, and the 2-1 surface 112B faces the gas sensor element 3G and the atmospheric pressure sensor element 3H.

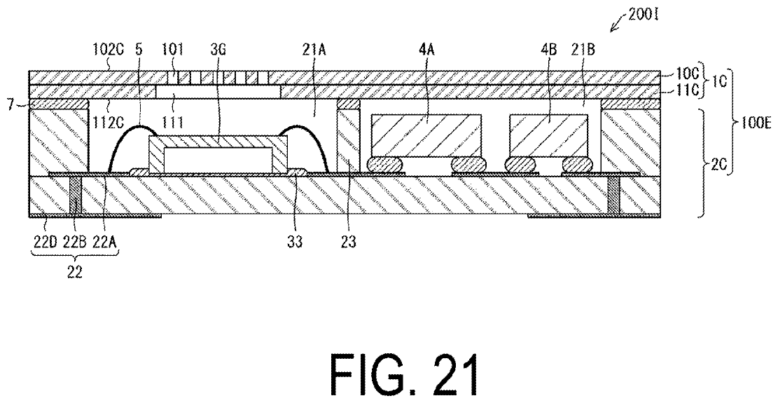

As in the wiring board 2B, a plurality of sensor elements 3 may be provided in one accommodation recess. A partition wall may be provided between the plurality of sensor elements (see the example illustrated in FIG. 21). While the example in which the gas sensor element 3G and the atmospheric pressure sensor element 3H are provided has been described with reference to FIG. 20, the type of the sensor element to be mounted and the number of sensor elements are not limited to those in the figure. The positions and the number of the first through holes 101 and the second through holes 111 may be changed as appropriate in accordance with the sensor element to be mounted. Specifically, a substrate having the configuration of the substrate 1 or the substrate 1A described above may be used instead of the substrate 1B.

FIG. 21 is a cross-sectional view of a sensor device 200I. The sensor device 200I includes a package 100E, the gas sensor element 3G, an ASIC 4A, and a capacitor 4B. The package 100E includes a substrate 1C, and a wiring board 2C including the wiring conductors 22. The wiring board 2C includes a partition wall 23 between the gas sensor element 3G on the one hand and the ASIC 4A and the capacitor 4B on the other, and thus includes a first accommodation recess 21A for accommodating the sensor element, and a second accommodation recess 21B for accommodating the ASIC 4A and the capacitor 4B.

The substrate 1C has a second layer 11C provided with the second through hole 111 at a position corresponding to the gas sensor element 3G, for example. The ASIC 4A and the capacitor 4B are desirably in an environment free of entrance of fluid such as gas or liquid, and thus are sealed airtight by the substrate 1C, the wiring board 2C, and the partition wall 23. A first layer 10C has the plurality of first through holes 101 in the second through hole 111, in plan view of the substrate 1C as viewed from a 2-1 surface 112C side. In the substrate 1C, a 1-1 surface 102C forms part of the outer surface of the package 100E, and the 2-1 surface 112C faces the gas sensor element 3G.

FIG. 21 is merely an example, and the types and numbers of sensor elements and other components to be mounted are not limited to those in the figure. The positions and the number of the first through holes 101 and the second through holes 111 may be changed as appropriate in accordance with the sensor element to be mounted. Specifically, a substrate having the configuration of the substrate 1, the substrate 1A, or the substrate 1B described above may be used instead of the substrate 1C.

### Third Embodiment

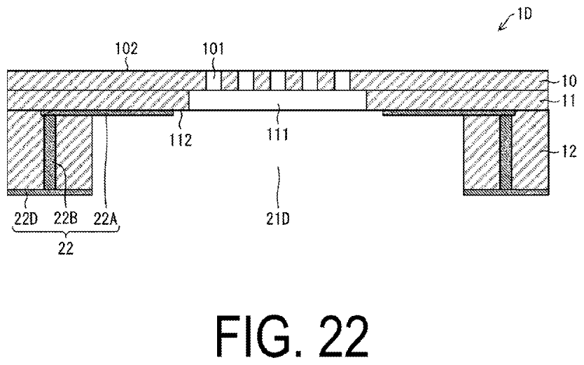

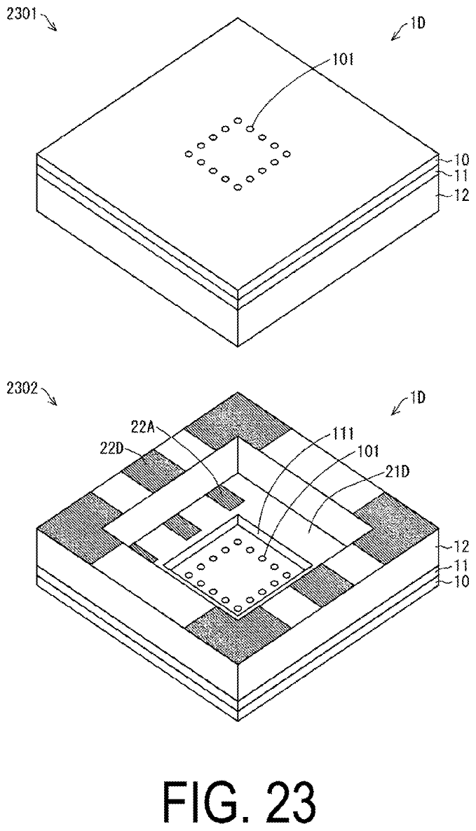

In the present embodiment, another embodiment of the substrate 1 according to the first embodiment will be described with reference to FIGS. 22 and 23. FIG. 22 is a cross-sectional view of an exemplary substrate 1D according to a third embodiment. Reference sign 2301 in FIG. 23 denotes a perspective view of the substrate 1D as viewed from the 1-1 surface 102 side, and reference sign 2302 denotes a perspective view of the substrate 1D as viewed from a frame portion 12 side.

As illustrated in FIGS. 22 and 23, the substrate 1D includes, for example, the first layer 10, the second layer 11, the frame portion 12 positioned on a surface of the second layer and surrounding the first through holes 101 and the second through hole 111, and the wiring conductors 22. Thus, the substrate 1D has a function of the wiring board to be mounted with the sensor element.

As with the first layer 10 and the second layer 11, the frame portion 12 is an insulation layer containing a ceramic material such as an aluminum oxide-based sintered body, a glass ceramic sintered body, a mullite-based sintered body, or an aluminum nitride-based sintered body, for example.

The substrate 1D includes an accommodation recess 21D defined by the frame portion 12. The shape and size of the accommodation recess 21D may be any shape and any size depending on the shape and size of the sensor element to be accommodated. For example, as illustrated in the view denoted by reference sign 2302 in FIG. 23, the accommodation recess 21D may have a rectangular parallelepiped shape. The shape of the inner side surface of the frame portion 12 is not particularly limited either. The inner side surface of the frame portion 12 may have a stepped shape or may be an inclined surface inclined with respect to the first layer 10 and the second layer 11.

The frame portion 12 includes the wiring conductors 22 in the inner portion and/or on a surface. Thus, the substrate 1D includes the wiring conductor 22 in the inner portion and on a surface. For example, as illustrated in FIG. 22, the substrate 1D includes, as the wiring conductors 22, a connection pad 22A for connection to the sensor element, and a terminal electrode 22D for connection to the external electrical circuit. The connection pad 22A and the terminal electrode 22D are electrically connected to each other by the through-hole conductor 22B and the internal wiring layer 22C (not illustrated) provided in the inner portion of the frame portion 12. The through-hole conductor 22B extends through the frame portion 12. The terminal electrode 22D may be provided not only at the upper surface but also from the upper surface to the outer side surface or on the outer side surface of the frame portion 12.

With the configuration described above, the sensor element is mounted on the bottom surface of the accommodation recess formed by the frame portion 12, and thus a substrate having breathability and waterproof property can be obtained. Specifically, a package can be obtained that has a structure in which a lid body having fine through holes and a wiring board to be mounted with a sensor element are integrated. Such a package is thinner than in cases where the lid body and the wiring board are separate bodies.

Since the sensor element is pressed against the substrate 1D in a process of mounting the sensor element on the substrate 1D, the substrate 1D according to the third embodiment needs to have strength. The substrate 1D includes the ceramic insulation layer and thus has excellent strength. Thus, the substrate 1D can be reduced in size or thickness, which contributes to reduction in size and thickness of a sensor device using the substrate 1D. With the frame portion 12 further layered on the first layer 10 or the second layer 11, the substrate 1D having an integrated structure can be easily manufactured.

In the substrate 1D, the dimensions of the second through hole 111 may be one size smaller than the dimensions of the sensor element to be mounted, and may have such a size that the sensor element can close the opening of the second through hole 111. For example, the opening area of the second through hole 111 can be 9% or more and 64% or less of the area of the sensor element in plan view.

### Variation 3-1

While FIG. 22 illustrates an example in which the substrate 1D is a laminate body including the first layer 10, the second layer 11, and the frame portion 12, the substrate 10A may be a laminate body including the first layer 10A, the second layer 11A including the plurality of second through holes 111, and the frame portion 12.

FIG. 22 illustrates an example in which the 1-1 surface 102 of the first layer 10 forms part of the outer surface of the substrate 1D, and the 2-1 surface 112 of the second layer 11 forms the bottom surface of the accommodation recess 21D. However, the 2-1 surface 112 of the second layer 11 may form part of the outer surface of the substrate 1D, and the 1-1 surface 102 may form the bottom surface of the accommodation recess 21D. The same applies to cases where the substrate 1D includes the first layer 10A, the second layer 11A, and the frame portion 12.

### Fourth Embodiment

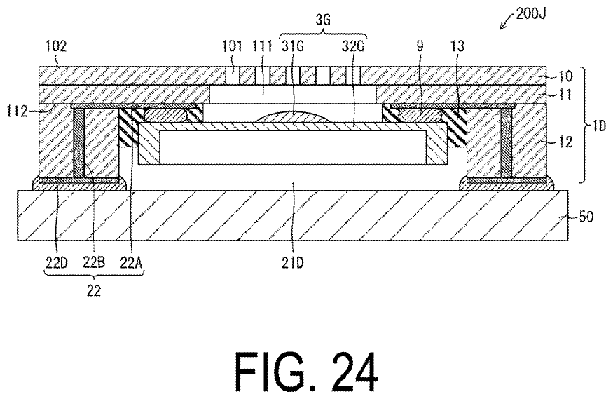

In a fourth embodiment, a gas sensor device 200J will be described in which the gas sensor element 3G as an example of a sensor element 3 is mounted on the substrate 1D described in the third embodiment. FIG. 24 is a cross-sectional view of the gas sensor device 200J. FIG. 24 illustrates a cross section in a state where the gas sensor device 200J is mounted on a mounting substrate 50. While the gas sensor device 200J mounted with the gas sensor element 3G will be described in the fourth embodiment, the sensor element to be mounted is not limited to the gas sensor element 3G. The configuration of the gas sensor device 200J illustrated as an example in the fourth embodiment may be applied to sensor devices in which a sensor element requiring that the package to be mounted with the sensor element have breathability is mounted. The sensor element 3 is, for example, a sensor that detects a property of a gas. More specifically, the sensor element 3 may be a gas sensor element, an atmospheric pressure sensor, a humidity sensor, or the like. The sensor element 3 may be an MEMS element, in which case the sensor device can have an even smaller size.

### Configuration of Gas Sensor Device 200J

The gas sensor device 200J includes the substrate 1D and the gas sensor element 3G.

The substrate 1D includes the first layer 10 that is a ceramic insulation layer including the plurality of first through holes 101, the second layer 11 including at least one second through hole 111, the frame portion 12, and the wiring conductors 22. The second layer 11 is layered on the first layer 10. The frame portion 12 is positioned on the surface of the second layer 11 and surrounds the first through holes 101 and the second through hole 111.

In the 1-1 surface 102 of the first layer 10, the first through hole 101 has, for example, a circular shape, and a diameter D1 of 10 μm or more and 50 μm or less. In the 2-1 surface 112 of the second layer, the second through hole 111 has, for example, a circular shape, and has a diameter D2 larger than the diameter D1 of the first through hole 101. At least some of the plurality of first through holes 101 overlap the second through hole 111 in plan view of the substrate 1D as viewed from the 1-1 surface 102 side of the first layer 10. In other words, the plurality of first through holes 101 overlap one second through hole 111. The second through hole 111 may have a quadrangular shape.

The gas sensor element 3G is flip-chip connected to the substrate 1D. Specifically, electrodes (not illustrated) provided on the surface of the support substrate 32G are each bonded to a respective one of the connection pad 22A using a conductive bonding material 9 such as gold bump and solder bump, for example, whereby the gas sensor element 3G is connected to the substrate 1D. A sealing member 13 that reduces the volume of a space communicating with the first through holes 101 is provided between the substrate 1D and the gas sensor element 3G. With the sealing member 13 provided, the space of the sensing portion provided with the gas sensing portion 31G can be independent of the other space in the accommodation recess 21D. With the space including the sensing portion reduced, the sensor sensitivity can be improved. With the space including the sensing portion being spatially independent, the spatial volume V communicating with the first through holes 101 is reduced. This inevitably increases the value of V′/V, and thus improves the waterproof performance.

The sealing member 13 may be an underfill material for reinforcing the bonding strength of the gas sensor element 3G to the substrate 1D using the conductive bonding material 9. The underfill material may be arranged not only around the conductive bonding material 9 such as gold bump or solder bump, but also along the entire circumference of the gas sensor element 3G (support substrate 32G) to fill the gap between the gas sensor element 3G and the substrate 1D, so that the sealing member 13 reducing the volume of the space communicating with the first through holes 101 is obtained.

In FIG. 24, the gas sensor element 3G is flip-chip connected to the substrate 1D, and thus the height for accommodating a bonding wire pad and a bonding loop is not required. As a result, the gas sensor device 200J can be further reduced in size and thickness. While the gas sensing portion 31G is positioned on the outer side of the second through hole 111, the gas sensing portion 31G may be accommodated in the second through hole 111 by adjusting the thickness of the conductive bonding material 9. With this configuration, the gas sensor device 200J can be further reduced in size.

In the substrate 1D, a dimension of the second through hole 111 (diameter or length of one side in a case of quadrangular shape) may be 30% or more and 80% or less of the diameter (length of one side) of the gas sensor element 3G. For example, when the diameter (or one side) of the gas sensor element 3G is 1 mm, the second through hole 111 may have a circular shape with a diameter of 0.3 mm or more and 0.8 mm or less, or a polygonal shape with one side being 0.3 mm or more and 0.8 mm or less. With this configuration, a protruding portion (gas sensing portion 31G) of the gas sensor element 3G can be accommodated in a recessed portion of the substrate 1 formed by the second through hole 111, so that the size can be further reduced. The gas sensing portion 31G can be arranged at a position close to the outer surface of the package 100. The air risen as a result of being heated in the gas sensing portion 31G is likely to accumulate in the second through hole 111 (recessed portion of the substrate), and thus discharge of the heated air is facilitated. Accordingly, more air outside the package can be taken in. This improves gas sensing sensitivity.

### Variation 4-1

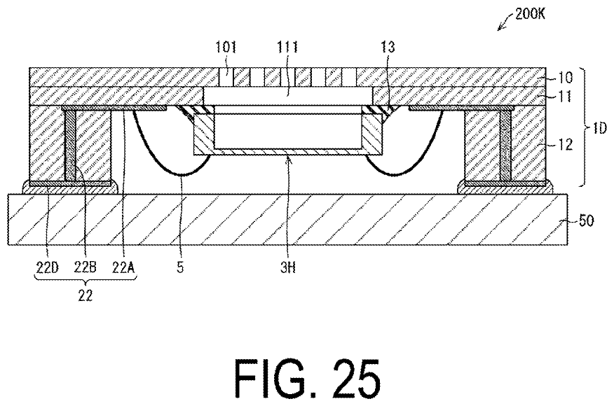

FIG. 25 is a cross-sectional view of another exemplary atmospheric pressure sensor device 200K according to the fourth embodiment. The atmospheric pressure sensor device 200K includes the substrate 1D and the atmospheric pressure sensor element 3H. The atmospheric pressure sensor device 200K is different from the gas sensor device 200J of the fourth embodiment in that the atmospheric pressure sensor element 3H is mounted as the sensor element, and in the mode of connection between the atmospheric pressure sensor element 3H and the substrate 1D.

The atmospheric pressure sensor element 3H includes electrodes (not illustrated), which are provided on the surface of the atmospheric pressure sensor element 3H and are each connected to a respective one of the connection pads 22A via the connecting member 5. FIG. 25 illustrates, as an example, the atmospheric pressure sensor device 200K mounted with the atmospheric pressure sensor element 3H. However, the sensor element to be mounted in the same and/or a similar mode is not limited to the atmospheric pressure sensor element 3H. A sensor element, such as the atmospheric pressure sensor element 3H, capable of performing detection based on air flowing from the lower surface side of the sensor element may be connected to the substrate 1D by wire bonding connection as illustrated in FIG. 25.

### Variation 4-2

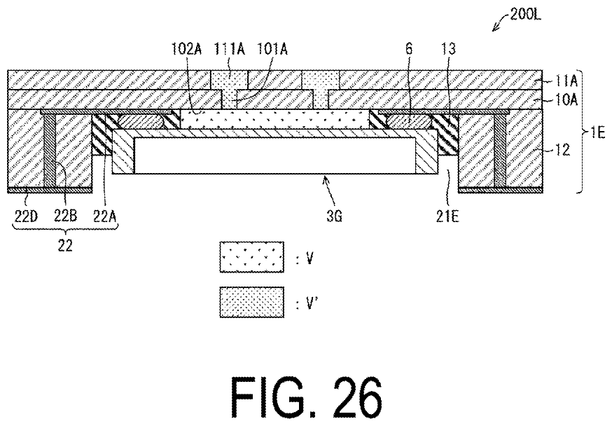

In a variation 4-2, a gas sensor device 200L will be described in which the gas sensor element 3G mounted on another exemplary substrate 1E according to the third embodiment (see FIG. 22). FIG. 26 is a cross-sectional view of the gas sensor device 200L.

The gas sensor device 200L includes the substrate 1E and the gas sensor element 3G. The substrate 1E includes the second layer 11A, the first layer 10A, the second layer 11A including the plurality of second through holes 111A on the surface of the first layer 1A, the frame portion 12 positioned surrounding the first through holes 101 and the second through holes 111, and the wiring conductors 22.

The substrate 1E includes an accommodation recess 21E defined by the frame portion 12. The substrate 1E includes, on the outer side of the first through holes 101A having excellent waterproof effect, the second through hole 111A having a diameter of 100 μm or more and 200 μm or less, whereby a stepwise waterproof structure is obtained, and waterproof effect can be further improved.

As in the gas sensor device 200J in FIG. 24, the gas sensor element 3G is flip-chip connected to the substrate 1E. The sealing member 13 that reduces the volume of a space communicating with the first through holes 101 is provided between the substrate 1E and the gas sensor element 3G. With the sealing member 13 provided, the space of the sensing portion can be independent of the other space in the accommodation recess 21E.

As illustrated in FIG. 26, the spatial volume V in the package, which communicates with the first through holes 101A, is defined by the 1-1 surface 102A, the sealing member 13, and the outer surface of the gas sensor element 3G. In this case, when the relationship between the spatial volume V and the sum V′ of volumes of the first through holes 101A and the second through hole 111A satisfies the condition of V′/V>0.3%, the possibility of water entering from the outside of the gas sensor device 200L can be significantly reduced. In the gas sensor device 200L, the gas sensor element 3G is flip-chip connected, leading to a smaller spatial volume V, and thus resulting in higher V′/V than with the gas sensor devices 200, and 200A to 200G in the examples illustrated in FIGS. 13 to 16, 18, and 19.

The gas sensor device 200J and the atmospheric pressure sensor device 200K use the substrate 1D or the substrate 1E including the frame portion 12. These sensor devices may also be mounted with an electronic component other than the sensor element 3 (the gas sensor elements 3G and the atmospheric pressure sensor element 3H), including an IC chip such as an ASIC chip and/or a capacitor. In this case, the electronic component may be mounted on the same surface as that of the sensor element 3 by increasing the inner dimension of the frame portion 12. The electronic component and the substrate may be electrically connected to each other by wire bonding, flip-chip connection, solder, or a conductive adhesive. The electronic component may be mounted on the sensor element 3 with the thickness of the frame portion 12 increased. In this case, connection to the substrate 1D or the substrate 1E may be made by wire bonding. These mounting methods can be appropriately selected depending on the size or thickness of the sensor device in plan view.

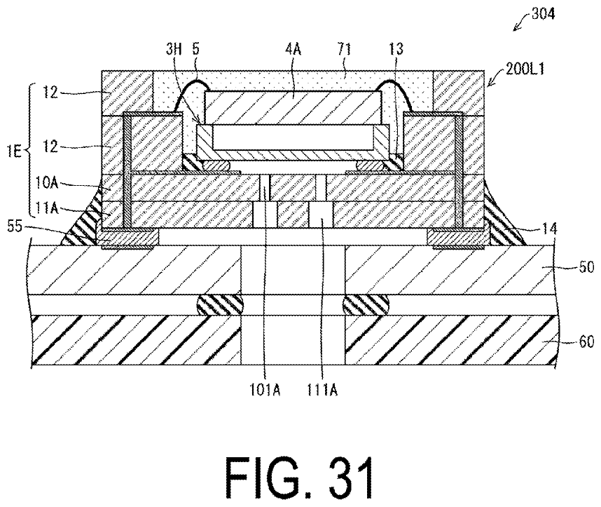

For example, as in an example illustrated in FIG. 31 described below, when an electronic component such as an ASIC is mounted on the sensor element, reduction in size in a planar direction can be achieved, whereby a sensor device with a small mounting area can be obtained. In this case, as in the example illustrated in FIG. 31, the internal space of the sensor element can be closed by the electronic component. Thus, the sensor element and the electronic component can be sealed with resin.

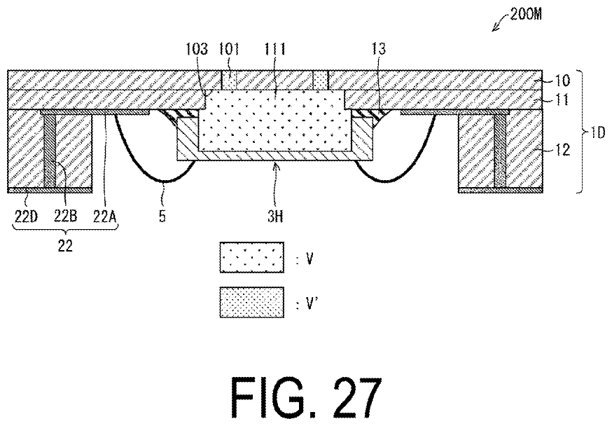

FIG. 27 is a cross-sectional view of an atmospheric pressure sensor device 200M having the same structure as the atmospheric pressure sensor device 200K described in the variation 4-1. When a sensor element having an internal space, such as the atmospheric pressure sensor element 3H, is connected by wire bonding, the spatial volume V in the package communicating with the first through holes 101A is defined as follows. Specifically, as illustrated in FIG. 27, the spatial volume V is a sum of the volume of the second through hole 111 and the internal spatial volume of the atmospheric pressure sensor element 3H. In this case, when the relationship between the spatial volume V and the sum V′ of volumes of the first through holes 101A satisfies the condition of V′/V>0.3%, the possibility of water entering from the outside of the atmospheric pressure sensor device 200M can be significantly reduced. The atmospheric pressure sensor device 200M, which is connected by wire bonding as with the gas sensor devices 200, and 200A to 200G illustrated in FIGS. 13 to 16, 18, and 19. However, the atmospheric pressure sensor device 200M is mounted with the atmospheric pressure sensor element 3H to close the second through hole 111. This further reduces the spatial volume V, whereby V′/V is further increased.

When the sensor element to be mounted is an MEMS element including a flat plate portion and a frame portion, V′/V is as described below with reference to FIGS. 24 to 27. Specifically, as illustrated in FIGS. 26 and 27, a higher V′/V is obtained in a case where the mounting is performed with an internal space of the sensor element surrounded by the frame portion and the flat plate portion facing the side opposite to the through hole (FIG. 26), than in a case where the mounting is performed with the internal space communicating with the through hole (FIG. 27). Thus, 200J has higher waterproof property than 200K.

Comparison between FIG. 24 and FIG. 26 indicates that a higher V′/V is obtained by the gas sensor device 200L including, as the through holes, the first through holes 101 on the frame portion 12 side and the second through hole 111, which is one size larger than the first through holes 101, on the side opposite to the frame portion 12. Thus, the gas sensor device 200L illustrated in FIG. 26 has better waterproof property than the gas sensor device 200J illustrated in FIG. 24.

The increase in V′/V can be more effectively achieved by reducing the spatial volume V based on the orientation of the sensor element mounted, than by increasing the volume V′ of the through holes based on the form, the number, the arrangement, or the like of the first through holes 101 and the second through hole 111.

The configurations of the first through holes 101, the second through hole 111, and the like described in the first embodiment can be applied as appropriate to the second to the fourth embodiments described above.

### Mounting Examples on Electronic Apparatus

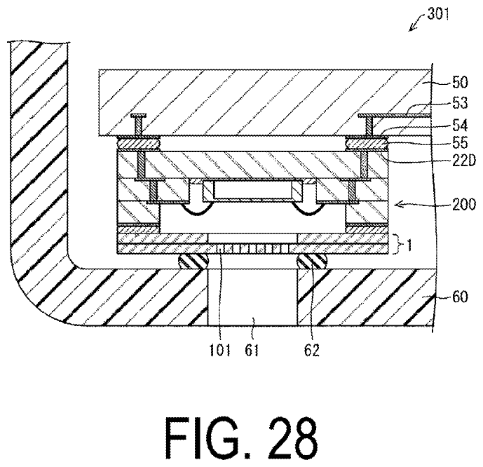

As example of an electronic apparatus mounted with a gas sensor device according to an aspect of the present disclosure will be described with reference to FIGS. 28 to 33. The mounting examples on the electronic apparatus described below are examples. The gas sensor device according to an aspect of the present disclosure may be mounted in electronic apparatuses in other known mounting modes. The gas sensor devices mounted in the electronic apparatuses described below are merely examples, and may be variously changed within the range of the present disclosure as a matter of course.

Specific examples of the electronic apparatus in which the gas sensor device according to an aspect of the present disclosure is mounted include, but are not limited to, information communication terminals such as smartphones, watches, game machines, and earphones.

The electronic apparatus according to an aspect of the present disclosure may be mounted with, for example, an atmospheric pressure sensor device including an atmospheric pressure sensor element or a humidity sensor device including a humidity sensor element instead of the gas sensor device.

### Mounting Example 1

FIG. 28 is a cross-sectional view of an electronic apparatus 301 including the gas sensor device 200 (see FIG. 13). FIG. 28 is a view around a portion in the electronic apparatus 301 where the gas sensor device 200 is mounted. Although not repeatedly described, the range illustrated in the cross-sectional view of the electronic apparatus is the same and/or similar in the mounting examples below as well.

As illustrated in FIG. 28, the electronic apparatus 301 includes the gas sensor device 200, the mounting substrate 50, and a housing 60 with an opening portion 61 serving as a ventilation hole formed therein.

The gas sensor device 200 is mounted on the mounting substrate 50. For example, the terminal electrodes 22D of the gas sensor device 200 are each bonded to a respective one of the external electrodes 54 of the mounting substrate 50 using a conductive bonding material such as solder. The mounting substrate 50 is, for example, a printed circuit board (PCB), and includes wiring 53 and the external electrodes 54.

In the electronic apparatus 301, the position of a portion, in the substrate 1 of the gas sensor device 200, including the plurality of first through holes 101 is arranged matching the position of the opening portion 61 of the housing 60. In other words, in the electronic apparatus 301, the gas sensor device 200 is mounted in the housing 60 with the first through holes 101 and the opening portion 61 communicating with each other. A sealing member 62 having a ring shape is arranged between the gas sensor device 200 and the housing 60, along the outer edge of the opening portion 61. With the sealing member 62, the first layer 10 and the housing 60 are bonded to each other, with the waterproof property secured between the first layer 10 of the substrate 1 of the gas sensor device 200 and the housing 60. The sealing member 62 may be a solder material, an O ring, or a gasket. Examples of the material of the sealing member 62 include rubber-based resin and metal such as solder.

### Mounting Example 2

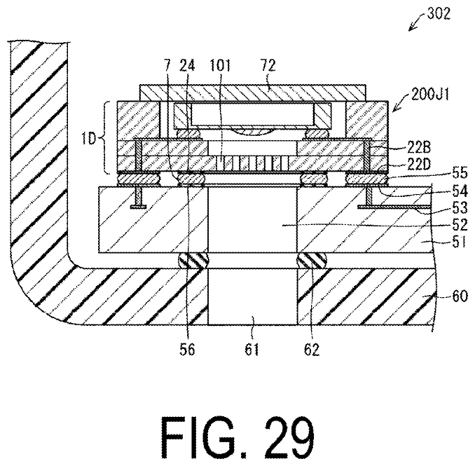

FIG. 29 is a cross-sectional view of an electronic apparatus 302 including a gas sensor device 200J1. As illustrated in FIG. 29, the electronic apparatus 302 includes the gas sensor device 200J1, a mounting substrate 51, and the housing 60. The gas sensor device 200J1 has a configuration similar to that of the gas sensor device 200J (see FIG. 24), but is different therefrom in that the through-hole conductors 22B extend through the first layer 10 and the second layer 11 of the substrate 1 instead of extending through the frame portion 12. The gas sensor device 200J1 includes a lid body 72, and the gas sensor element 3G is sealed and protected by the lid body 72. The gas sensor device 200J1 includes the terminal electrodes 22D on the surface of the first layer 10. The terminal electrodes 22D are each connected to a respective one of the through-hole conductors 22B. The gas sensor device 200J1 need not include the sealing member 13.

The mounting substrate 51 is, for example, a printed circuit board (PCB) including an opening portion 52, and includes wiring 53 and the external electrodes 54.

In the electronic apparatus 302, the position of a portion, in the substrate 1D of the gas sensor device 200J1, including the plurality of first through holes 101 is arranged matching the position of the opening portion 52 of the mounting substrate 51. In other words, in the electronic apparatus 302, the gas sensor device 200J1 is mounted on the mounting substrate 51, with the first through holes 101 and the opening portion 52 arranged communicating with each other. For example, the terminal electrodes 22D of the gas sensor device 200J1 are each bonded to a respective one of the external electrodes 54 of the mounting substrate 51 using a conductive bonding material 55 such as solder. Thus, the gas sensor device 200J1 is electrically connected to the wiring 53 of the mounting substrate 51. A sealing ring 56 is formed on the surface of the mounting substrate 51 facing the gas sensor device 200J1 and surrounds the outer circumference of the opening portion 52. In the gas sensor device 200J1, a sealing ring 24 having the same shape as that of the sealing ring 56 is formed at a position facing the mounting substrate 51. The sealing ring 56 and the sealing ring 24 are bonded to each other with the sealing bonding material 7. The sealing ring 56 and the sealing ring 24 are each formed as a metal layer such as a metallized layer or plating layer of the conductor material.

In the electronic apparatus 302, the mounting substrate 51 is mounted in the housing 60, with the position of the opening portion 52 of the mounting substrate 51 arranged matching the position of the opening portion 61 of the housing 60. The sealing member 62 having a ring shape is arranged between the mounting substrate 51 and the housing 60, along the outer edge of the opening portion 61.

### Mounting Example 3

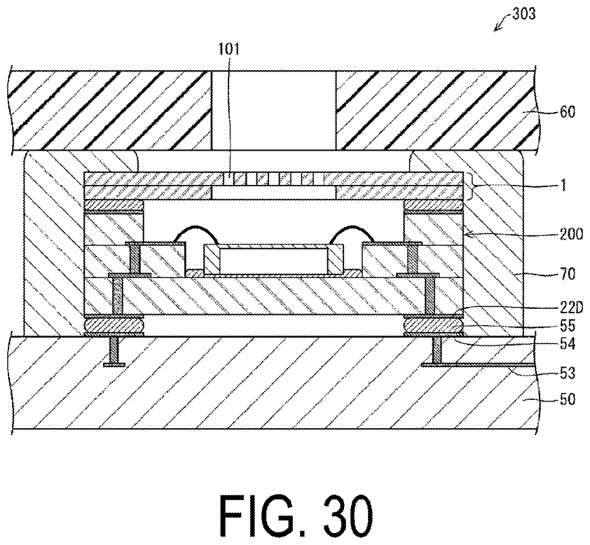

FIG. 30 is a cross-sectional view of an electronic apparatus 303 including the gas sensor device 200. As illustrated in FIG. 30, the electronic apparatus 303 includes the gas sensor device 200, the mounting substrate 50, the housing 60, and a gasket 70. The gas sensor device 200 is mounted on the mounting substrate 50.

In the electronic apparatus 303, the gas sensor device 200 is bonded to the housing 60 using the gasket 70, with the position of a portion, in the substrate 1 of the gas sensor device 200, including the plurality of first through holes 101 arranged matching the position of the opening portion 61 of the housing 60. The gasket 70 has a shape of, for example, an inward flange extending from the mounting substrate 50 to the housing 60. The gasket 70 covers the periphery of the gas sensor device 200 and also covers part of the first layer 10 of the gas sensor device 200 so as to secure waterproof property between the first layer 10 and the housing 60. The material of the gasket 70 may be a rubber-based resin or the like, and is not particularly limited.

### Mounting Example 4

FIG. 31 is a cross-sectional view of an electronic apparatus 304 including an atmospheric pressure sensor device 200L1. As illustrated in FIG. 31, the electronic apparatus 304 has a configuration similar to that of the electronic apparatus 302 of Mounting Example 2 described above, but is different therefrom in that the electronic apparatus 304 includes the atmospheric pressure sensor device 200L1. The atmospheric pressure sensor device 200L1 is different from the gas sensor device 200L (see FIG. 26) in the following configurations. (i) The atmospheric pressure sensor device 200L1 is mounted with the atmospheric pressure sensor element 3H instead of the gas sensor element 3G. (ii) The ASIC 4A is mounted on the atmospheric pressure sensor device 200L1. (iii) The accommodation recess of the atmospheric pressure sensor device 200L1 is filled with a sealing body 71.

The sealing body 71 may be a resin power compact or may be formed using other materials. For example, the sealing body 71 can be formed by coating (potting) with resin or the like. The sealing member 13 is not necessarily required because the filling is performed with the sealing body 71.

The atmospheric pressure sensor device 200L1 is bonded to the mounting substrate 50 via the conductive bonding material 55. In the bonded portion, as illustrated in FIG. 31, the periphery of the atmospheric pressure sensor device 200L1 may be sealed using a sealing material 14 such as resin. Thus, the internal space of the atmospheric pressure sensor device 200L1 communicating with the outside of the electronic apparatus 304 is independent of the internal space of the electronic apparatus 304.

### Mounting Example 5

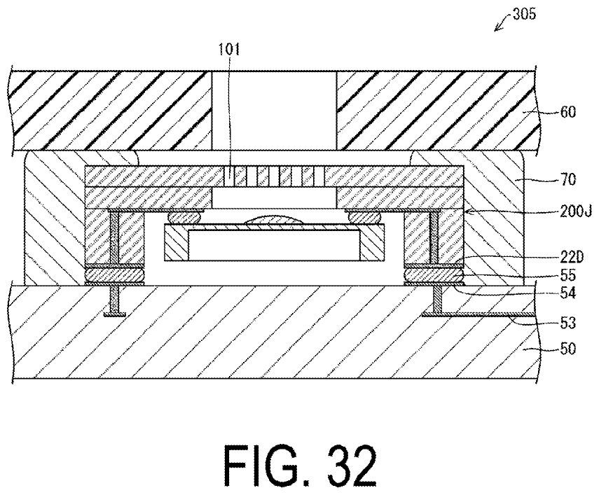

FIG. 32 is a cross-sectional view of an electronic apparatus 305 including the gas sensor device 200J (see FIG. 24). As illustrated in FIG. 32, the electronic apparatus 305 has a configuration similar to that of the electronic apparatus 303 of Mounting Example 3 described above, but is different therefrom in that the electronic apparatus 305 includes the gas sensor device 200J instead of the gas sensor device 200. For example, in the electronic apparatus 305, the terminal electrodes 22D of the gas sensor device 200J are each bonded to a respective electrode of the mounting substrate 50 using a conductive bonding material 55 such as solder.

The gasket 70 is bonded to the mounting substrate 50 via the conductive bonding material 55. In the electronic apparatus 305, the gas sensor device 200J need not include the sealing member 13.

### Mounting Example 6

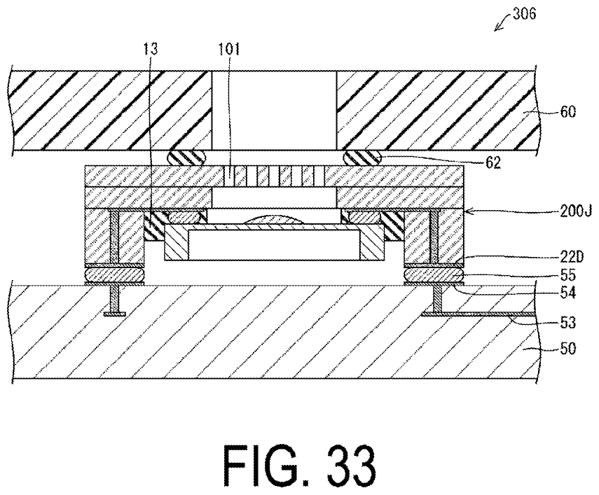

FIG. 33 is a cross-sectional view of an electronic apparatus 306 including the gas sensor device 200J (see FIG. 24). As illustrated in FIG. 33, the electronic apparatus 306 has a configuration similar to that of the electronic apparatus 305 of Mounting Example 5 described above, but is different therefrom in that the electronic apparatus 306 includes the sealing member 62 instead of the gasket 70. In the electronic apparatus 306, the sealing member 62 having a ring shape is arranged between the gas sensor device 200J and the housing 60, along the outer edge of the opening portion 61.

### REFERENCE SIGNS

1, 1A, 1B, 1C, 1D, 1E Substrate
2, 2A, 2B, 2C Wiring board
3 Sensor element (3G: Gas sensor element, 3H: atmospheric pressure sensor element)
12 Frame portion
13 Sealing member
21, 21D, 21E Accommodation recess
22 Wiring conductor
31G Gas sensing portion
50, 51 Mounting substrate
60 Housing
100, 100A, 100B, 100C, 100D, 100E Package
101, 101A, 101B, 101C, 101D, 101E, 101F, 101G, 101H, 101I First through hole
111, 111′, 111A Second through hole
200, 200A, 200B, 200C, 200D, 200E, 200F, 200G, 200J, 200J1, 200J2, 200L Gas sensor device (sensor device)
200H, 200I Sensor device
200K Atmospheric pressure sensor device (sensor device)
301, 302, 303, 304, 305, 306 Electronic apparatus

1. A substrate comprising:
a first layer that is a ceramic insulation layer comprising a plurality of first through holes; and
a second layer layered on the first layer, the second layer being a ceramic insulation layer comprising at least one second through hole, wherein
the plurality of first through holes each have a diameter of from 10 to 50 μm,
the at least one second through hole has a diameter larger than the diameter of each of the plurality of first through holes, and
at least some of the plurality of first through holes overlap the at least one second through hole in plan view of the first layer.

2. The substrate according to claim 1, wherein
the first layer has a thickness of from 50 to 150 μm.

3. The substrate according to claim 1, wherein
the plurality of first through holes overlap one of the at least one second through hole in plan view of the second layer.

4. The substrate according to claim 1, wherein
the second layer comprises a plurality of the second through holes.

5. The substrate according to claim 1, wherein
a smaller angle of angles between a line segment formed by an inner wall surface of each of the plurality of first through holes in a cross section taken along a plane orthogonal to a surface of the first layer and a line segment formed by the surface of the first layer in the cross section is 80° or more and 90° or less.

6. The substrate according to claim 1, wherein
a line connecting a center of one opening portion and a center of another opening portion of each of the plurality of first through holes is inclined with respect to a surface of the first layer by 90°±10°.

7. The substrate according to claim 1, wherein
in plan view of the second layer, the plurality of first through holes are positioned away from an outer edge of the at least one second through hole.

8. The substrate according to claim 1, wherein
the plurality of first through holes have a staggered arrangement in plan view of the first layer.

9. The substrate according to claim 1, further comprising:
a frame portion positioned on a surface of the first layer or the second layer and surrounding the plurality of first through holes and the at least one second through hole, and
a wiring conductor positioned in an inner portion of the frame portion or on a surface of the frame portion.

10. The substrate according to claim 9, wherein
the frame portion is positioned on a surface of the first layer, and
the at least one second through hole has a diameter of 100 μm or more and 200 μm or less.

11. A package comprising:
the substrate according to claim 1 serving as a lid body; and
a wiring board comprising an accommodation recess and wiring, the accommodation recess being configured to accommodate a sensor element, wherein
the first layer is located on a side of the accommodation recess,
the at least one second through hole has a diameter of 100 μm or more and 200 μm or less, and
V′/V≥0.05%, where V is a volume defined by a surface of the first layer on the side of the accommodation recess and the accommodation recess, and V′ is a sum of volumes of the plurality of first through holes and the at least one second through hole.

12. A sensor device comprising:
the substrate according to claim 1; and
a sensor element.

13. A sensor device comprising:
the substrate according to claim 10; and
a sensor element, wherein
the sensor element is mounted on the substrate in the frame portion, and
V′/V>0.3%, where V is a volume of a space between the substrate and the sensor element, and V′ is a sum of volumes of the plurality of first through holes and the at least one second through hole.

14. A sensor device comprising:
the package according to claim 11; and
a sensor element.

15. The sensor device according to claim 12, wherein
the sensor element is a gas sensor element configured to detect a property of gas.

16. An electronic apparatus comprising the sensor device according to claim 12.

17. A package comprising:
a first substrate comprising an accommodation recess configured to accommodate a sensor element; and
a second substrate configured to close the accommodation recess, wherein
the second substrate comprises:
a first layer that is a ceramic insulation layer comprising a plurality of first through holes; and
a second layer layered on the first layer, the second layer being a ceramic insulation layer comprising at least one second through hole,
the plurality of first through holes each have a diameter of from 10 to 50 μm,
the at least one second through hole has a diameter larger than the diameter of each of the plurality of first through holes,
at least some of the plurality of first through holes overlap the at least one second through hole in plan view of the first layer, and
the second layer is located on a side of the accommodation recess.

18. A substrate to be mounted with a sensor element, the substrate comprising:
a first layer that is a ceramic insulation layer comprising a plurality of first through holes;
a second layer layered on the first layer, the second layer being a ceramic insulation layer comprising at least one second through hole;
a frame portion positioned on a surface of the second layer and surrounding the plurality of first through holes and the at least one second through hole; and
a wiring conductor, wherein
the plurality of first through holes each have a diameter of from 10 to 50 μm,
the at least one second through hole has a diameter larger than the diameter of each of the plurality of first through holes, and
at least some of the plurality of first through holes overlap the at least one second through hole in plan view of the first layer.

19. A sensor device comprising:
the package according to claim 17; and
a sensor element.

20. A sensor device comprising:
the substrate according to claim 18; and
a sensor element.

21. The sensor device according to claim 20, wherein the sensor element is flip-chip connected to the substrate.

22. The sensor device according to claim 20, further comprising
a sealing member between the substrate and the sensor element, the sealing member reducing a volume of a space communicating with the plurality of first through holes.

23. The sensor device according to claim 20, wherein
the sensor element is a gas sensor element,
the gas sensor element comprises a gas sensing portion protruding toward the substrate, and
the gas sensing portion is accommodated in the at least one second through hole.

24. An electronic apparatus comprising the sensor device according to claim 19.
